(19) United States
(12) Patent Application Publication
(10) Pub. No.: US 2016/0064452 A1
(43) Pub. Date: Mar. 3, 2016

(54) MEMORY DEVICE

(71) Applicant: KABUSHIKI KAISHA TOSHIBA, Tokyo (JP)

(72) Inventors: Yoshihiro UEDA, Yokohama Kanagawa (JP); Tsukasa NAKAI, Yokkaichi Mie (JP); Masaki KONDO, Yokkaichi Mie (JP); Hikari TAJIMA, Koganei Tokyo (JP); Hiroki TOKUHIRA, Kawasaki Kanagawa (JP); Takashi IZUMIDA, Yokohama Kanagawa (JP)

(73) Assignee: KABUSHIKI KAISHA TOSHIBA, Tokyo (JP)

(21) Appl. No.: 14/594,782

(22) Filed: Jan. 12, 2015

Related U.S. Application Data
(60) Provisional application No. 62/041,856, filed on Aug. 26, 2014.

(51) Int. Cl. H01L 27/24; H01L 43/02; G11C 29/04; H01L 45/00; G11C 11/16; G11C 13/00; H01L 27/22; H01L 43/08

(52) U.S. Cl. CPC H01L 27/2436; H01L 27/228; H01L 43/02; H01L 43/08; H01L 45/1233; G11C 11/1655; G11C 11/1673; G11C 11/1675; G11C 13/0026; G11C 13/004; G11C 13/0069; G11C 29/04

(57) ABSTRACT

A memory device according to an embodiment includes a memory element; and a transistor including a semiconductor layer and a plurality of gates, wherein the plurality of gates include: a first set of gates, the gates being disposed in a manner to sandwich the semiconductor layer, and a second set of gates, the gates being disposed in a manner to sandwich the semiconductor layer, the gates included in the first set is disposed in a manner to separate from the gates included in the second set in a direction along a side surface of the semiconductor layer.

### CROSS REFERENCE TO RELATED APPLICATIONS

This application claims the benefit of U.S. Provisional Application No. 62/041,856, filed Aug. 26, 2014, the entire contents of which are incorporated herein by reference.

### FIELD

Embodiments described herein relate generally to a memory device.

### BACKGROUND

As a memory device, there is known, for instance, a resistance change type memory device using a resistance change element.

### BRIEF DESCRIPTION OF THE DRAWINGS

FIG. 1 illustrates an example of a block configuration of a memory device according to a first embodiment.

FIG. 2 schematically illustrates a layout of the memory device according to the first embodiment.

FIG. 3A illustrates an example of a circuit configuration of memory cells of the memory device according to the first embodiment.

FIG. 3B illustrates an example of a circuit configuration of select transistors of the memory device according to the first embodiment.

FIG. 4 illustrates an example of a circuit configuration of a memory cell array of the memory device according to the first embodiment.

FIG. 5 illustrates a configuration example of a block of the memory device according to the first embodiment.

FIG. 6A schematically illustrates a configuration example of the memory cell array of the memory device according to the first embodiment.

FIG. 6B schematically illustrates a configuration example of a select gate of the memory device according to the first embodiment.

FIG. 7 schematically illustrates a layout of the memory cell array of the memory device according to the first embodiment.

FIG. 8 schematically illustrates an example of a wiring structure between transistors according to the first embodiment.

FIG. 9 schematically illustrates an example of another wiring structure between transistors according to the first embodiment.

FIG. 10 schematically illustrates an example of voltage values at a time of operations of transistors according to the first embodiment.

FIG. 11 illustrates an example of a circuit configuration of a memory cell array of a memory device according to a second embodiment.

FIG. 12 illustrates an example of another circuit configuration of the memory cell array of the memory device according to the second embodiment.

FIG. 13 schematically illustrates a configuration example of the memory cell array of the memory device according to the second embodiment.

FIG. 14 schematically illustrates a layout of the memory cell array of the memory device according to the second embodiment.

FIG. 15 illustrates an example of a block configuration of a memory device and a memory controller according to a third embodiment.

FIG. 16 schematically illustrates an example of mapping of blocks of the memory device according to the third embodiment.

FIG. 17 illustrates a flow of a mapping operation of blocks of the memory device according to the third embodiment.

FIG. 18 illustrates a part of items described in a specification of the memory device according to the third embodiment.

FIG. 19A schematically illustrates an example of the operation of a memory device according to a fourth embodiment.

FIG. 19B schematically illustrates a layout of a memory cell array and a row decoder of the memory device according to the fourth embodiment.

### DETAILED DESCRIPTION

There is a case in which a hierarchical bit line method is adopted as a circuit configuration of a memory device such as a resistance change type memory device. In the hierarchical bit line method, a plurality of bit lines are connected to a global bit line via select transistors. A plurality of memory cells are connected to these bit lines. Each memory cell includes a memory element such as a resistance change type element, and a cell transistor. When an operation of, e.g. write and read is executed for one memory element, a current is supplied to the memory element, which is a target of operation, via a bit line.

However, with an increase in the number of memory cells, an area of disposition of these transistors, which is occupied in the memory device, is increasing.

According to an embodiment to be described below, the transistor can be reduced in size. Specifically, a memory device of the embodiment includes a memory element; and a transistor including a semiconductor layer and a plurality of gates, wherein the plurality of gates include: a first set of gates, the gates being disposed in a manner to sandwich the semiconductor layer, and a second set of gates, the gates being disposed in a manner to sandwich the semiconductor layer, the gates included in the first set is disposed in a manner to separate from the gates included in the second set in a direction along a side surface of the semiconductor layer, and when the transistor is turned on, at least a gate on one side of the semiconductor layer in the first set is activated, and at least a gate on the other side of the semiconductor layer in the second set is activated.

This embodiment will be described hereinafter with reference to the accompanying drawings. In the drawings the same parts are denoted by like reference numerals. In addition, an overlapping description is given where necessary.

In the description below, when the word “connection” is simply used, this means physical connection, and the meaning includes direct connection or indirect connection via some other element. When the word “electrical connection” is used, this means an electrically conductive state, and the meaning includes direct connection or indirect connection via some other element.

### First Embodiment

A memory device according to the present embodiment will now be described. The memory device according to this embodiment is, for example, a resistance change type memory device using a resistance change element as a memory element. To be more specific, the memory device according to this embodiment is, for example, an SST (Spin-Transfer Torque)-type MRAM (Magnetoresistive Random Access Memory) functioning as a magnetic memory device which uses as a memory element an MTJ (Magnetic Tunnel Junction) element functioning as a magnetoresistive effect element.

### (1) Configuration Example of Resistance Change Type Memory Device

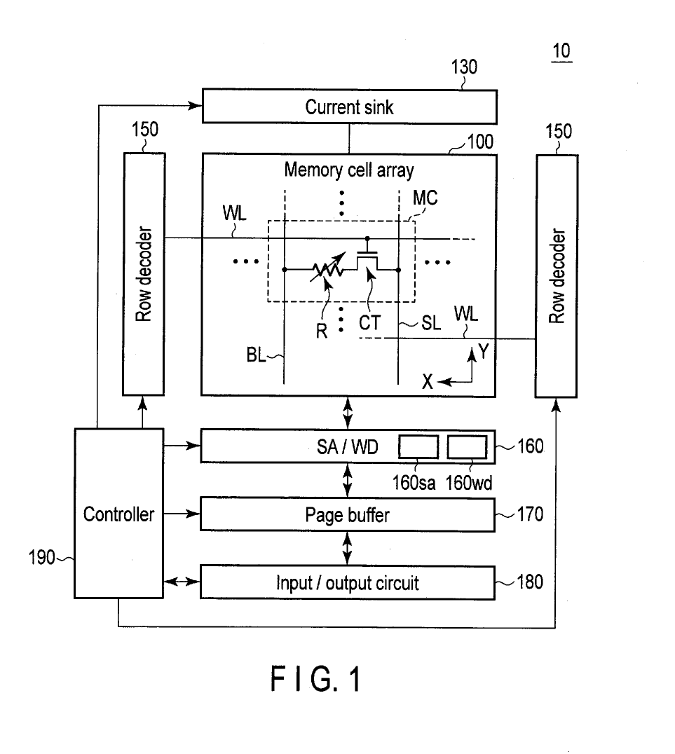

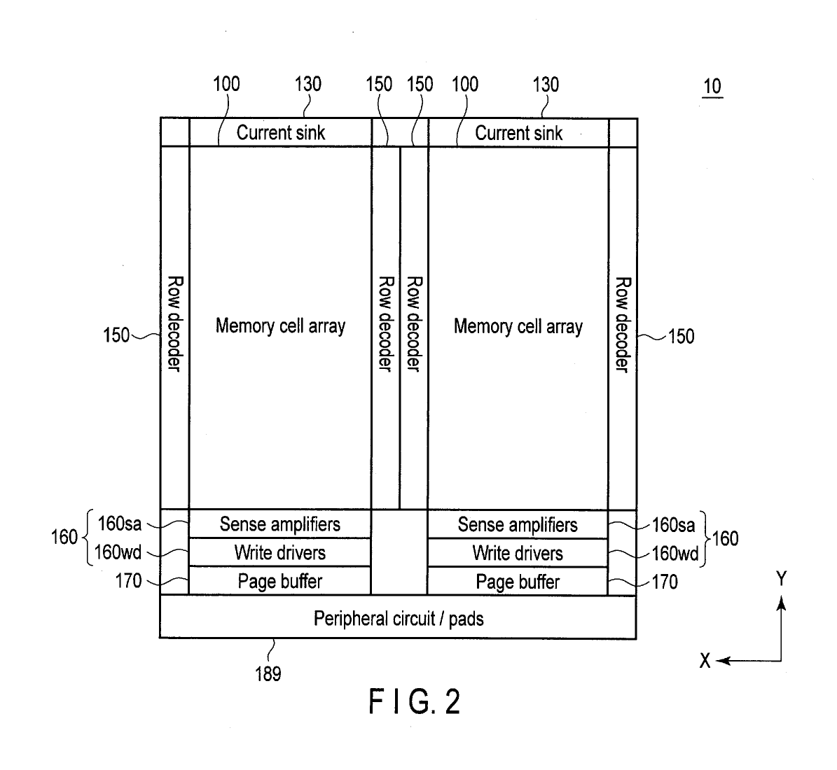

Referring to FIG. 1 and FIG. 2, a description is given of a configuration example of an MRAM 10 functioning as the memory device according to the present embodiment.

FIG. 1 illustrates an example of a block configuration of the memory device according to the present embodiment.

As illustrated in FIG. 1, the MRAM 10 includes a memory cell array 100, a current sink 130, row decoders 150, a sense amplifier and write driver (SA/WD) 160, a page buffer 170, an input/output circuit 180, and a controller 190. The MRAM 10 includes at least one memory cell array 100.

The memory cell array 100 includes a plurality of memory cells MC, and a select gate (not shown). The plural memory cells MC are arranged in a matrix in the memory cell array 100. A plurality of memory cells MC, which are arranged in each row in an X direction (row direction), are connected to a common word line WL of a plurality of word lines WL extending in the X direction in the memory cell array 100. A plurality of memory cells MC, which are arranged in each column in a Y direction (column direction), are connected to a common bit line and source line pair BL, SL, of a plurality of bit lines BL and source lines SL paired with the bit liens BL, which extend in the Y direction in the memory cell array 100.

The memory cell MC includes an MTJ element R functioning as a memory element (resistance change element), and a cell transistor CT. The MTJ element R is configured such that the MTJ element R can store data by a variation of a resistance state thereof. The MTJ element R is configured such that data is written or read out by various electric currents being supplied to the MTJ element R. The cell transistor CT is connected in series to the MTJ element R, and configured to control the supply and stop of an electric current to the MTJ element R. The cell transistor CT is turned on, thereby starting current supply, and the cell transistor CT is turned off, thereby stopping current supply. At one end of the MTJ element R, the memory cell MC is connected to one of the paired bit line BL and source line SL, for example, the bit line BL. Further, at one end of the current path of the cell transistor CT, the memory cell MC is connected to the other of the paired bit line BL and source line SL, for example, the source line SL. Furthermore, at the gate of the cell transistor CT, the memory cell MC is connected to the word line WL. However, in the structure of the cell transistor CT, the gate and the word line WL are not distinguished, and the gate of the cell transistor CT is substantially identical to the word line WL.

The select gate connects the bit line BL to a global bit line, and connects the source line SL to a global source line. To be more specific, the select gate includes a plurality of select transistors, and each select transistor is connected to the bit line BL or source line SL. The select transistor, which is connected to the bit line BL, is configured to electrically connect one bit line BL to the global bit line by an ON/OFF operation. The select transistor, which is connected to the source line SL, is configured to electrically connect one source line SL to the global source line by an ON/OFF operation. In this manner, the select gate functions as a switch which electrically connect one memory cell MC of a plurality of memory cells MC to the SA/WD 160.

The SA/WD 160 is connected to the global bit line and the global source line. The SA/WD 160 supplies a current to the memory cell MC, which is the target of operation, via the global bit line and the bit line BL, and via the global source line and the source line SL, and executes write and read for the memory cell MC (MTJ element R). To be more specific, a write driver 160wd of the SA/WD 160 executes write in the memory cell MC. A sense amplifier 160sa of the SA/WD 160 executes read from the memory cell MC.

The current sink 130 is connected to one end of the global bit line and one end of the global source line. In an operation such as write and read of data, the current sink 130 sets the global bit line or global source line at a ground potential.

The row decoders 150 are disposed, for example, on both sides of the memory cell array 100 in the X direction, and are connected to the plural word lines WL. The row decoders 150 are decode a row address of a command address signal. Further, in an operation such as write and read of data, the row decoders 150 are configured to apply a voltage to the word line WL which is connected to the memory cell MC of the target of operation, in accordance with this row address.

The page buffer 170 temporarily stores, in a data unit called “page”, the data which is to be written in the memory cell array 100, and the data which has been read out of the memory cell array 100. The data unit per page may be, for example, 8 kB.

The input/output circuit 180 sends various signals, which have been received from the outside, to the controller 190 and the page buffer 170, and sends various information from the controller 190 and the page buffer 170 to the outside.

The controller 190 is connected to the current sink 130, the row decoder 150, the SA/WD 160, the page buffer 170, and the input/output circuit 180. The controller 190 controls the current sink 130, the row decoder 150, the SA/WD 160, and the page buffer 170 in accordance with signals which have been received by the input/output circuit 180 from the outside.

A layout of the circuit configuration of FIG. 1 is illustrated in FIG. 2. FIG. 2 schematically illustrates a layout of the memory device according to the present embodiment.

As illustrated in FIG. 2, the MRAM 10 includes, for example, a plurality of memory cell arrays 100. Around each memory cell array 100, there are disposed other structures associated with the memory cell array 100, for instance, the current sink 130, the row decoders 150, the SA/WD 160 (sense amplifier 160sa and write driver 160wd), the page buffer 170, the peripheral circuit 189 and pads. The select gates not illustrated in FIG. 2 are disposed, for example, on the SA/WD 160 side in the memory cell array 100, and on the current sink 130 side in the memory cell array 100. The peripheral circuit 189 includes, for example, the input/output circuit 180, the controller 190, and a power supply.

### (2) Circuit Configuration Example of Transistors

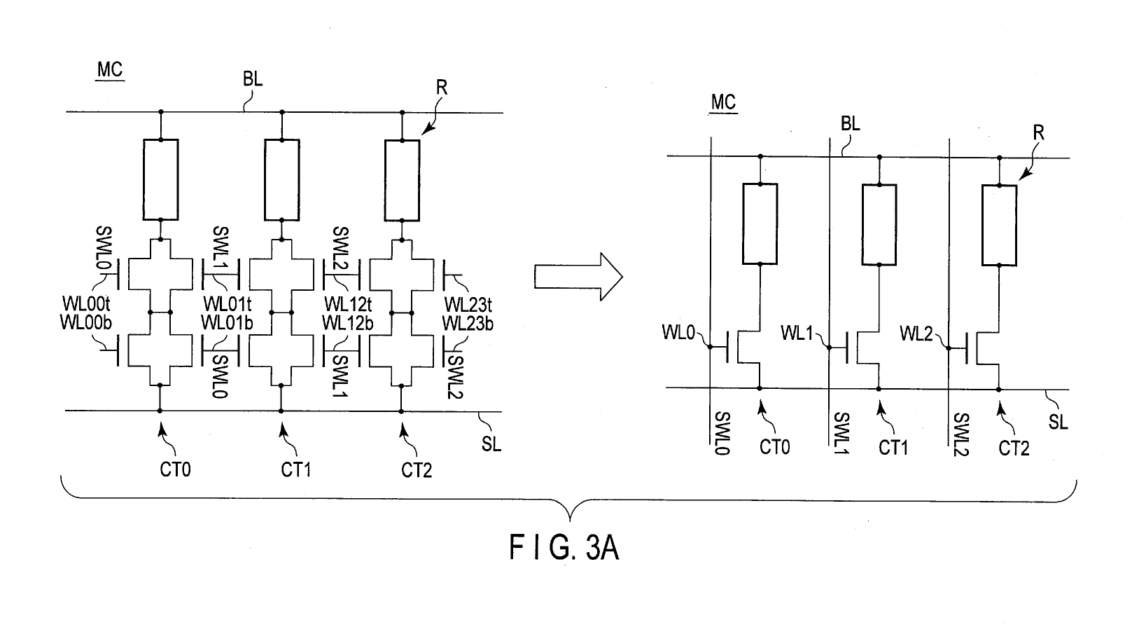

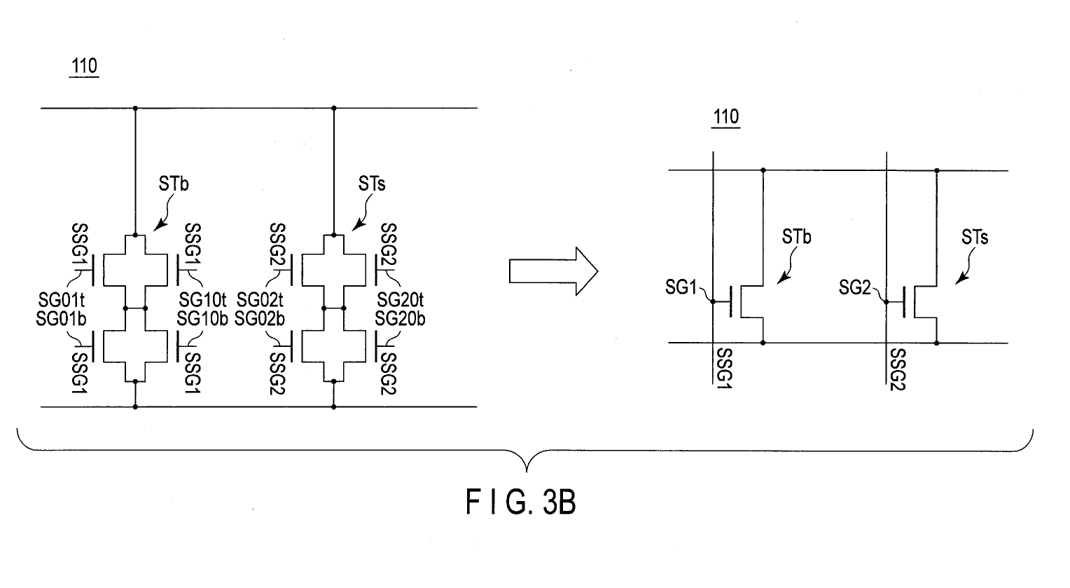

Referring to FIG. 3A and FIG. 3B, a description is given of an example of the circuit configuration of various transistors of the MRAM 10. FIG. 3A illustrates an example of the circuit configuration of memory cells of the memory device according to the present embodiment. FIG. 3B illustrates an example of the circuit configuration of select transistors of the memory device according to the present embodiment.

As illustrated in FIG. 3A and FIG. 3B, the cell transistor CT and the select transistor ST are configured as, for example, transistors including two-stage double-gates. Specifically, the cell transistor CT and the select transistor ST have such configurations that a set of two gates is disposed in two stages (sets). As described above, the select transistors ST are transistors included in a select gate 110. The select transistors ST include a select transistor STb which is connected to the bit line BL, and a select transistor STs which is connected to the source line SL. These select transistors STb, STs have the same structure.

As illustrated in FIG. 3A, gates of two stages between neighboring cell transistors CT are shared. In other words, neighboring cell transistors CT are connected to common word lines. Specifically, cell transistors CT0, CT1 are connected to common word lines WL01b, WL01t, respectively. Cell transistors CT1, CT2 are connected to common word lines WL12b, WL12t, respectively. The cell transistor CT0 is also connected to word lines WL00b, WL00t. The cell transistor CT2 is also connected to word lines WL23b, WL23t.

A common signal SWL0 is delivered to the word lines WL01b, WL00t of the cell transistor CT0. A common signal SWL1 is delivered to the word lines WL12b, WL01t of the cell transistor CT1. A common signal SWL2 is delivered to the word lines WL23b, WL12t of the cell transistor CT2.

In the meantime, in the drawings to be referred to below, the cell transistors CT of the memory cells MC are illustrated in a simplified manner as shown in the right part of FIG. 3A.

As illustrated in FIG. 3B, the gates of the two stages of each select transistor ST are not shared with other select transistors ST, and the gates are connected to the individual select gate lines SG. Specifically, the select transistor STb is connected to select gate lines SG01b, SG10b, SG01t, SG10t. The select transistor STs is connected to select gate lines SG02b, SG20b, SG02t, SG20t. Incidentally, in the structure of the select transistor ST, the gate and the select gate line SG are not distinguished, and the gate of the select transistor is substantially identical to the select gate line SG.

A common signal SSG1 is delivered to the select gate lines SG01b, SG10b, SG01t, SG10t of the select transistor STb. A common signal SSG2 is delivered to the select gate lines SG02b, SG20b, SG02t, SG20t of the select transistor STs.

Incidentally, in the drawings to be referred to below, the select transistors ST of the select gate 110 are illustrated in a simplified manner as shown in the right part of FIG. 3B.

### (3) Circuit Configuration Example of Resistance Change Type Memory Device

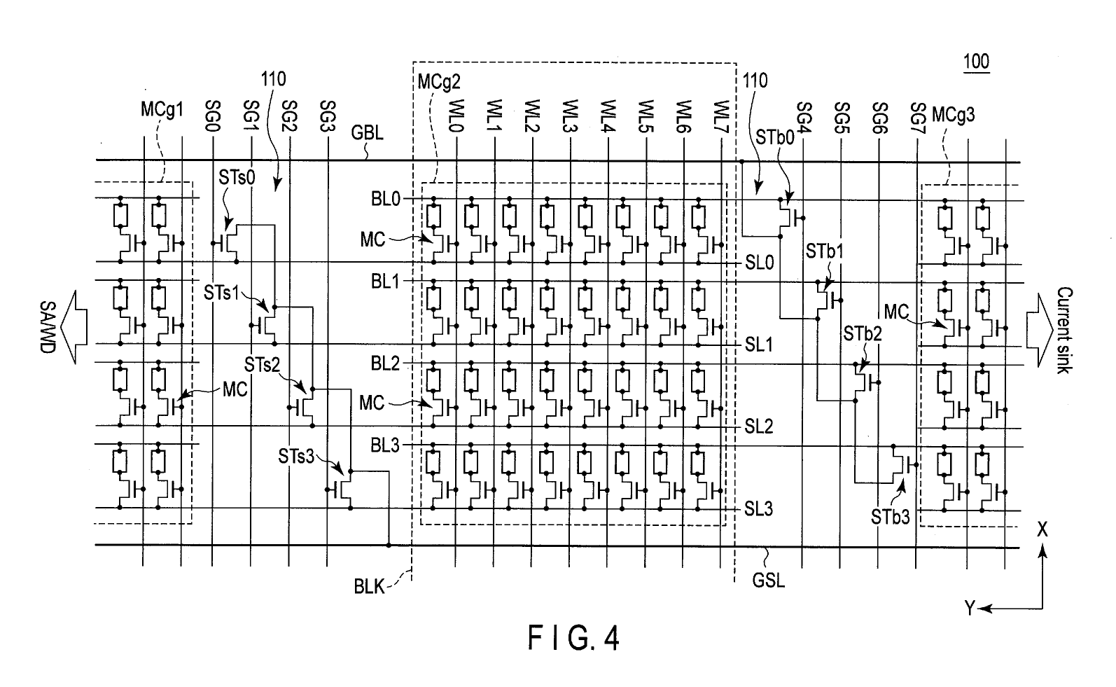

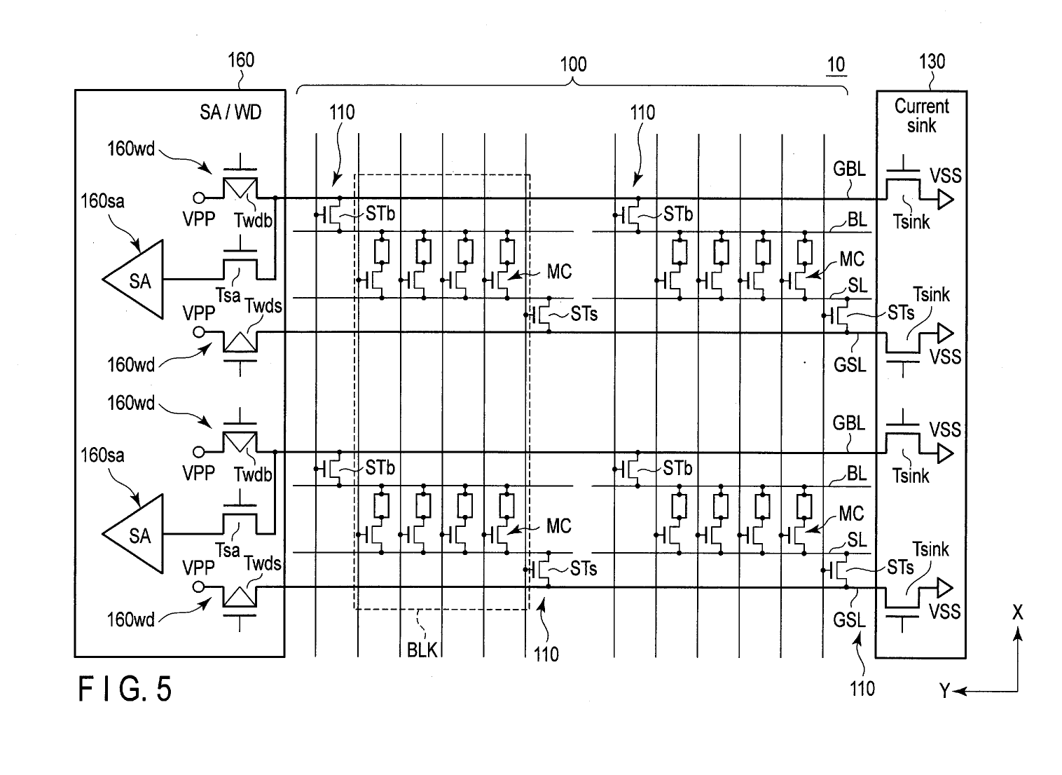

Referring to FIG. 4 and FIG. 5, an example of the circuit configuration of the MRAM 10 is described.

FIG. 4 illustrates an example of the circuit configuration of the memory cell array of the memory device according to the present embodiment.

As illustrated in FIG. 4, the MRAM 10 includes a global bit line GBL functioning as a global wiring line, and a global source line GSL functioning as a global wiring line which is paired with the global bit line GBL. Memory cell groups MCg (MCg1 to MCg3), in which a plurality of memory cells MC are arranged in a matrix, are included between the global bit line GBL and the global source line GSL.

Bit lines BL (BL0 to BL3) functioning as local wiring lines are shared by the memory cell groups MCg2, MCg3, which are disposed on both sides of select transistors STb (STb0 to STb3) functioning as first select transistors. The select transistors STb, which are disposed between the memory cell groups MCg2, MCg3, are also shared by the memory cell groups MCg2, MCg3. Source lines SL (SL0 to SL3) functioning as local wiring lines are shared by the memory cell groups MCg1, MCg2, which are disposed on both sides of select transistors STs functioning as second select transistors. The select transistors STs, which are disposed between the memory cell groups MCg1, MCg2, are also shared by the memory cell groups MCg1, MCg2.

A plurality of memory cells MC, which are arranged in the Y direction, are commonly connected to the bit line BL and the source line SL which is paired with this bit line BL. The respective bit lines BL are connected to the global bit line GBL via the select transistors STb. The respective source lines SL are connected to the global source line GSL via the select transistors STs. The select transistors STb and the select transistors STs are included in the select gate 110. A plurality of memory cells MC, which are arranged in the X direction, are commonly connected to the word line WL (WL0 to WL7). The respective select transistors STb, STs are connected to the corresponding select gate lines SG (SG0 to SG7).

To be more specific, the global bit line GBL is connected to a first terminal of the select transistor STb. A second terminal of the select transistor STb is connected to one end of the MTJ element R via the bit line BL. The other end of the MTJ element R is connected to a first terminal of the cell transistor CT. A second terminal of the cell transistor CT is connected to a first terminal of the select transistor STs via the source line SL. A second terminal of the select transistor STs is connected to the global source line GSL.

The gate, functioning as a control node, of the cell transistor CT is connected to the word line WL. The gate, functioning as a control node, of the select transistor STb is connected to the select gate line SG (SG4 to SG7). The gate, functioning as a control node, of the select transistor STs is connected to the select gate line SG (SG0 to SG3).

By the above, a current path is constituted from the global bit line GBL to the global source line GSL via the bit line BL, the memory cell MC, and the source line SL. Specifically, any one of the plural select transistors STb and the select transistor STs, which is paired with this one of the select transistors STb, are turned on, and thereby one bit line BL is electrically connected to the global bit line GBL, and the source line SL, which is paired with this bit line BL, is electrically connected to the global source line GSL. The cell transistor CT of one of the memory cells MC, which are connected to these bit line BL and source line SL, is turned on, and thereby one memory cell MC is selected.

As described above, the MRAM 10 has a circuit configuration of a hierarchical bit line method in which, for example, the select transistors STb are provided in one stage. Further, the circuit configuration of the MRAM 10 is also a hierarchical source line method in which the select transistors STs are provided in one stage.

The plural memory cells MC, which are interposed between the select transistors STb, STs, constitute at least a part of a block BLK. The block BLK includes a plurality of memory cells MC which are commonly connected to a plurality of word lines WL.

FIG. 5 illustrates a configuration example of a block of the memory device according to the present embodiment. FIG. 5 illustrates, in particular, the memory cell array 100, current sink 130 and SA/WD 160.

As illustrated in FIG. 5, the MRAM 10 includes a plurality of pairs of global bit lines GBL and global source lines GSL. Memory cells MC and select transistors STb, STs are disposed between the global bit line GBL and the global source line GSL. In FIG. 5, the structure interposed between the global bit line GBL and the global source line GSL is depicted in a simplified manner.

A plurality of word lines WL extend in the X direction over a plurality of pairs of global bit lines GBL and global source lines GSL. As described above, the memory cells MC, which are commonly connected to these plural word lines WL, are included in one block BLK.

Specifically, one block BLK includes a set of plural memory cells MC which are disposed by sharing plural word lines WL between the select transistors STb and the select transistors STs which are paired with these select transistors STb. The plural select transistors STs, which, together with the select transistors STb, sandwich the plural memory cells MC connected commonly to the plural word lines WL, function as block gate transistors which partition one block BLK. The select transistors STb, STs may be included in one block BLK.

Each of the global bit lines GBL and the global source lines GSL has one end connected to the SA/WD 160 and has the other end connected to the current sink 130.

To be more specific, one end of the global bit line GBL is connected via a transistor Tsa to a sense amplifier 160sa which is included in the SA/WD 160, with such configuration that a read current can be supplied to the global bit line GBL. Further, the one end of the global bit line GBL is connected to a second terminal of a transistor Twdb which is included in a write driver 160wd of the SA/WD 160. A first terminal of the transistor Twdb is connected to a power supply voltage VPP, with such configuration that a write current can be supplied to the global bit line GBL. The other end of the global bit line GBL is connected to a first terminal of a transistor Tsink which is included in the current sink 130. A second terminal of the transistor Tsink is connected to a ground potential VSS, and is a terminal end of a current of a write and read operation in the memory cell array 100.

One end of the global source line GSL is connected to a second terminal of a transistor Twds which is included in the write driver 160wd of the SA/WD 160. A first terminal of the transistor Twds is connected to a power supply voltage VPP, with such configuration that a write current can be supplied to the global source line GSL. The other end of the global source line GSL is connected to a first terminal of a transistor Tsink which is included in the current sink 130. A second terminal of the transistor Tsink is connected to a ground potential VSS, and is a terminal end of a current of a write and read operation in the memory cell array 100.

### (4) Configuration Example of Memory Cell Array

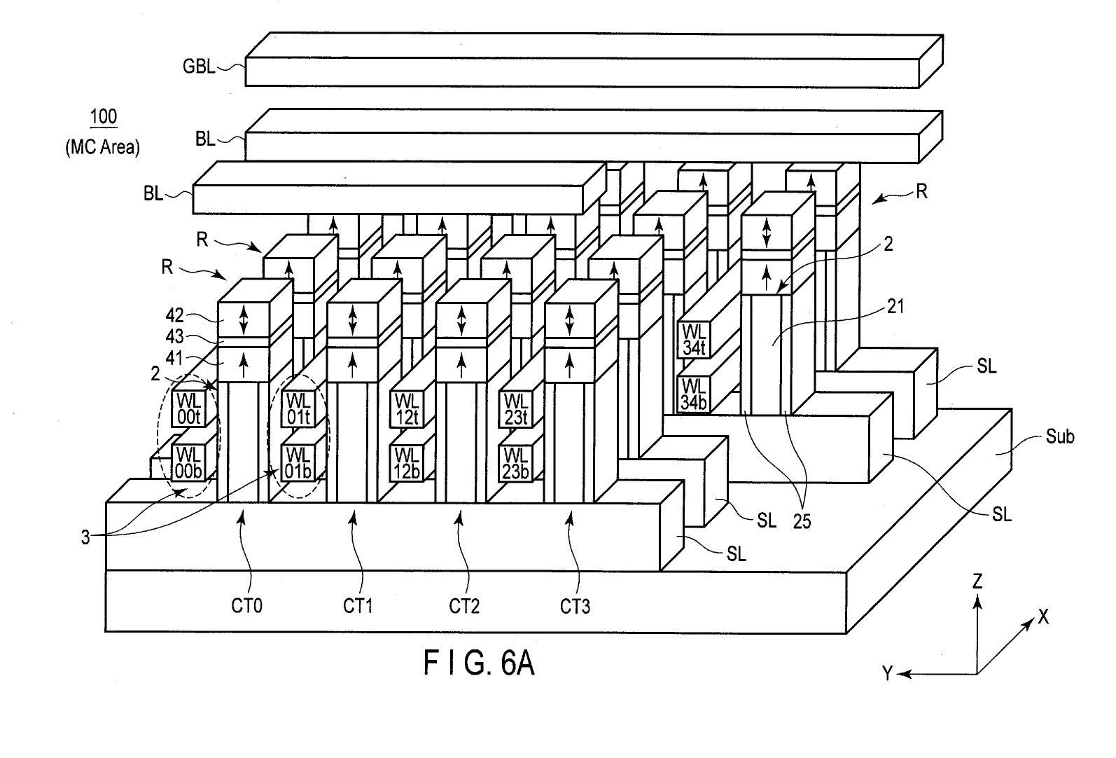

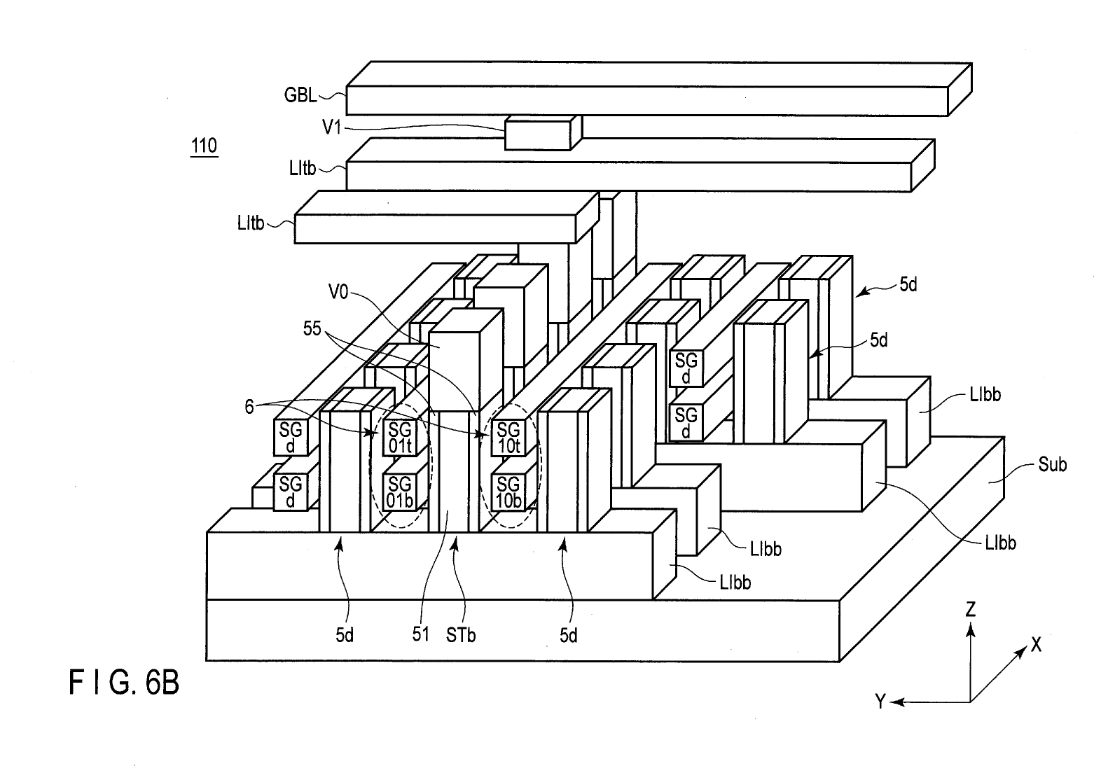

Referring to FIG. 6A to FIG. 9, a description is given of a configuration example of the memory cell array 100 of the MRAM 10.

[Memory Cell Region]

FIG. 6A schematically illustrates a configuration example of the memory cell array of the memory device according to the present embodiment. FIG. 6A illustrates, in particular, a region (hereinafter, also referred to as “memory cell MC region”) in the memory cell array 100, where the memory cells MC are disposed.

As illustrated in FIG. 6A, in the memory cell array 100, a plurality of source lines SL extending in the Y direction are disposed above in a Z direction of a substrate Sub. A plurality of cell transistors CT are arranged in a matrix above in the Z direction of the source lines SL. An MTJ element R is disposed above in the Z direction of each cell transistor CT. A plurality of bit lines BL, a global bit line GBL and a global source line GSL (not shown), which extend in the Y direction, are disposed above in the Z direction of the MTJ elements R. The bit lines BL are disposed, for example, at an M0 wiring level, and the global bit line GBL and the global source line GSL are disposed, for example, at an M1 wiring level which is a higher layer than the M0 wiring level. A plurality of cell transistors CT, which are arranged in the Y direction, are connected to a common source line SL. A plurality of MTJ elements R, which are arranged in the Y direction, are connected to a common bit line BL.

In this manner, the MRAM 10 has a memory cell array configuration of a source line isolation type.

The substrate Sub can be composed of various materials other than an insulative material, and contains, as a main component, for instance, silicon (Si), polysilicon (Poly-Si), or tungsten (W). The source line SL may contain the same kind of material as the substrate Sub as a main component, and may be formed by processing a part of the substrate Sub. When the source line SL contains, for instance, silicon as a main component, the source line SL may be formed by diffusing impurities in a part of the substrate Sub. The bit line BL contains, for instance, a metal such as tungsten (W) as a main component. The global bit line GBL and the global source line GSL contain, for instance, a metal such as copper (Cu) as a main component.

(Cell Transistor)

The cell transistor CT includes a channel portion 2 and two-stage double-gates 3. The cell transistor CT is composed of the channel portion 2 extending in the Z direction and the two-stage double-gates 3, for example, as a vertical transistor, to be more specific, as a two-stage double-gate vertical type transistor. The cell transistor CT is also composed as a gate-shared type transistor in which the two-stage double-gates 3 are shared.

The channel portion 2 includes a semiconductor layer 21, and the gate insulation layers 25 covering at least parts of both side surfaces in the Y direction of the semiconductor layer 21. The semiconductor layer 21 is, for example, an n⁺ type semiconductor layer having an n⁺ type as a certain conductivity type. The n⁺ type semiconductor layer contains, as a main component, for example, silicon doped with impurities which become a donor. The semiconductor layer 21 may be formed by processing a part of the substrate Sub.

By including the above-described channel portion 2, the cell transistor CT is constructed as, for example, an n-channel type TFT (Thin Film Transistor). However, the semiconductor layer 21 may be a p⁻ type semiconductor layer having a p⁻ type as a certain conductivity type. The p⁻ type semiconductor layer contains, as a main component, for example, silicon doped with impurities which become an acceptor. In this case, the cell transistor CT is constructed as, for example, a p-channel type TFT.

The gates of the two-stage double-gates 3 correspond to the above-described word lines WL. The word line WL contains, for example, polysilicon as a main component, and extends in the X direction between the channel portions 2 in the Y direction.

To be more specific, the word lines WL are disposed in a manner to sandwich the channel portion 2 in two stages along the side surfaces of the semiconductor layer 21. Specifically, the first-stage word line WL is disposed at such a position that the center in the Z direction of this word line WL does not overlap the center in the Z direction of the semiconductor layer 21, and is located at a height between the center in the Z direction of the semiconductor layer 21 and the lower end of the semiconductor layer 21. The second-stage word line WL is disposed at such a position that the center in the Z direction of this word line WL does not overlap the center in the Z direction of the semiconductor layer 21, and is located at a height between the center in the Z direction of the semiconductor layer 21 and the upper end of the semiconductor layer 21.

In this manner, for example, four word lines WL are disposed for one channel portion 2. These word lines WL are shared between neighboring cell transistors CT. For example, the cell transistor CT0 includes word lines WL00b, WL01b, WL00t, WL01t. The cell transistor CT1 includes word lines WL01b, WL12b, WL01t, WL12t. The word lines WL01b and WL01t of the cell transistor CT1 are shared with the cell transistor CT0. The same applies to CT2, CT3, . . . .

When the cell transistor CT is to be turned on, the word lines WL are operated as described below.

Specifically, among the four word lines WL around the channel portion 2, an H level voltage (e.g. a power supply voltage VPP) is applied to the word line WL on one side of the channel portion 2 in the first stage, and the H level voltage is applied to the word line WL on the other side of the channel portion 2 in the second stage. Thereby, the cell transistor CT is turned on. Specifically, in the cell transistor CT0, for instance, the H level voltage is applied to the word line WL01b on one side in the first stage, and the H level voltage is applied to the word line WL00t on the other side in the second stage. Thereby, the cell transistor CT0 is turned on. A voltage of an L level (e.g. a ground potential VSS) is applied to the other word lines WL including the word lines WL00b, WL01t. In other words, as illustrated in FIG. 3A, the common signal SWL0 having the H level potential is applied to the word lines WL01b, WL00t, and the signal SWL having the L level potential is applied to the other word lines WL. In the cell transistor CT1, the H level voltage is applied to the word line WL12b on one side in the first stage, and the H level voltage is applied to the word line WL01t on the other side in the second stage. Thereby, the cell transistor CT1 is turned on. The L level voltage is applied to the other word lines WL including the word lines WL01b, WL12t. In other words, as illustrated in FIG. 3A, the common signal SWL1 having the H level potential is applied to the word lines WL12b, WL01t, and the signal SWL having the L level potential is applied to the other word lines WL. The same applies to the cell transistors CT2, CT3, . . . .

However, the word lines WL, to which the H level voltage is applied, and the word lines WL, to which the L level voltage is applied, may be reversed. In this case, the pair of word lines WL, to which the common signal SWL is applied, is also reversed. Specifically, for example, when the cell transistor CT0 is turned on, the common H level signal SWL may be applied to the word lines WL00b, WL01t, and the L level signal SWL may be applied to the word lines WL01b, WL00t.

In this manner, in association with one channel portion 2, those word lines WL of the first-stage and second-stage word lines WL, which are located at obliquely crossing positions with the channel portion 2 interposed, are activated, and thereby the cell transistor CT is turned on.

(MTJ Element)

The MTJ element R functioning as a magnetoresistive effect element is configured to have different resistance states in accordance with the direction of an electric current flowing through the MTJ element R. A phenomenon in which a different resistance is exhibited in accordance with a state is called “magnetoresistive effect”. The MTJ element R stores data by using the magnetoresistive effect.

A magnetic tunnel junction included in the MTJ element R includes, at least, a fixed layer 41, a recording layer 42, and an insulation layer 43 between these layers. The magnetization of the fixed layer 41 is fixed. The recording layer 42 has magnetization which changes in accordance with the direction of write current flowing through the layer. The MTJ element R may include upper and lower electrode layers (not shown) which are provided in a manner to sandwich the fixed layer 41, the recording layer 42, and the insulation layer 43.

The MTJ element R exhibits different resistance states, depending on the relative relationship between the direction of magnetization of the fixed layer 41 and the direction of magnetization of the recording layer 42. Specifically, in the MTJ element R, these different resistance states are associated with, for example, two values of one-bit data, depending on whether the directions of magnetization of the fixed layer 41 and the recording layer 42 are in a parallel state (low-resistance state) or in an antiparallel state (high-resistance state).

[Select Gate]

FIG. 6B schematically illustrates a configuration example of the select gate of the memory device according to the present embodiment. The select transistor STb, which is connected to the bit line BL, and the select transistor STs, which is connected to the source line SL, have the same structure. In FIG. 6B, the select transistor STb is illustrated.

As illustrated in FIG. 6B, in the select gate 110, a plurality of lower-layer wiring lines LIbb extending in the Y direction are disposed above in the Z direction of the substrate Sub. A plurality of select transistors STb are arranged in a matrix above in the Z direction of the lower-layer wiring lines LIbb. A plurality of upper-layer wiring lines LItb and a global bit line GBL, which extend in the Y direction, are disposed above in the Z direction of the select transistors STb. The upper-layer wiring lines LItb are disposed, for example, at the M0 wiring level.

The lower-layer wiring line LIbb may contain the same kind of material as the substrate Sub as a main component, such as silicon (Si), polysilicon (Poly-Si), or tungsten (W). The lower-layer wiring line LIbb may be formed by processing a part of the substrate Sub. When the lower-layer wiring line LIbb contains, for instance, silicon as a main component, the lower-layer wiring line LIbb may be formed by diffusing impurities in a part of the substrate Sub. The upper-layer wiring line LItb contains, for instance, a metal such as tungsten (W) as a main component.

(Select Transistor)

The select transistor STb of the select gate 110 includes a channel portion 5 and two-stage double-gates 6, and has substantially the same configuration as the above-described cell transistor CT. Specifically, the select transistor STb is composed as a vertical transistor, to be more specific, as a two-stage double-gate vertical type transistor.

However, the select transistor STb does not have another select transistor STb neighboring in the Y direction, and the two-stage double-gates 6 of the select transistor STb are occupied by the individual select transistor STb. In short, the select transistor STb is not a gate-shared type transistor.

Further, the select transistor STb does not have a memory element such as an MTJ element R, and is connected to the global bit line GBL via, for example, contacts V0, V1 and the upper-layer wiring line LItb. A plurality of select transistors STb, which are arranged in the Y direction, are connected to the common upper-layer wiring line LItb and lower-layer wiring line LIbb.

The channel portion 5 includes a semiconductor layer 51, and gate insulation layers 55 covering at least parts of both side surfaces in the Y direction of the semiconductor layer 51. The semiconductor layer 51 is, for example, an n⁺ type semiconductor layer having an n⁺ type as a certain conductivity type. The semiconductor layer 51 may be a p⁻ type semiconductor layer having a p⁻ type as a certain conductivity type. Dummy channel portions 5d may be disposed at positions neighboring the channel portion 5 on both sides of the channel portion 5. The dummy channel portion 5d includes, for example, a semiconductor layer in which no impurities are intentionally included, and insulation layers covering both side surfaces of the semiconductor layer, and does not electrically operate. Specifically, the dummy channel portion 5d may have the same potential as the lower-layer wiring line LIbb (e.g. the same as a source line potential), or may be in a floating state.

Select gate lines SG, which are gates of the two-stage double-gates 6, are disposed in a manner to sandwich the channel portion 5 in two stages along side surfaces of the semiconductor layer 51. In the dummy channel portion 5d, dummy gates SGd may be disposed in two stages on the side opposite to the channel portion 5.

Like the case of the cell transistor CT, when the select transistor STb is to be turned on, it should suffice if among of those select gate lines SG of the first-stage and second-stage, the select gate lines SG, which are disposed at obliquely crossing positions with the channel portion 5 interposed, are activated.

However, in the select transistor STb of the present embodiment, for example, all of four select gate lines SG are activated. Specifically, in the first stage and second stage of the two-stage double-gates 6, the select gate lines SG01b, SG10b, SG01t, SG10t on both sides of the channel portion 5 are activated. In other words, as illustrated in FIG. 3B, the common signal SSG having the H level potential is delivered to the select gate lines SG01b, SG10b, SG01t, SG10t. The common signal SSG having the L level potential is delivered to the dummy gate SGd of the dummy channel portion 5d.

As described above, the select transistor STs has the same structure as the select transistor STb. Specifically, the structure of the select transistor STs is described by replacing the description of the bit lines BL and the global bit line GBL in connection with the above-described select transistor STb with the description of the source lines SL and the global source line GSL.

[Layout and Wiring Configuration]

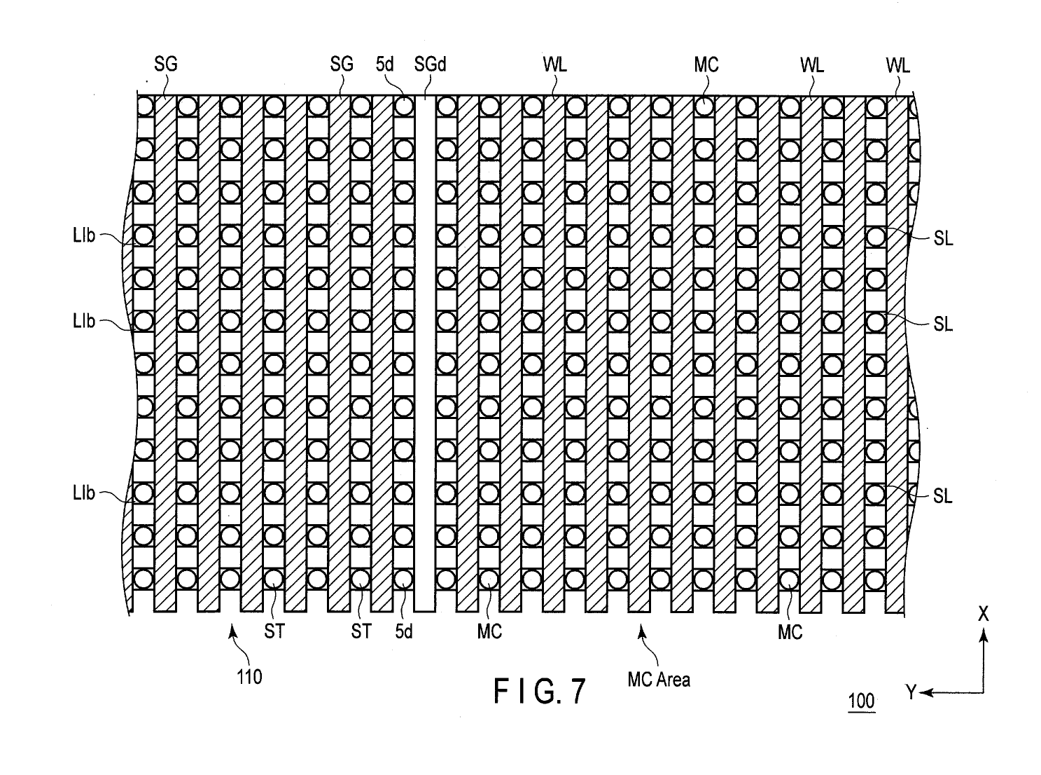

FIG. 7 schematically illustrates a layout of the memory cell array of the memory device according to the present embodiment. Since the select transistors STb and STs have the same structure, these are not distinguished in FIG. 7.

As illustrated in FIG. 7, a memory cell MC area and a select gate 110 in the memory cell array 100 are partitioned by, for example, dummy channel portions 5d and a dummy gate SGd on one side thereof. In the memory cell MC area, a plurality of source lines SL extending in the Y direction are disposed. A plurality of memory cells MC (MTJ elements R and cell transistors CT) are disposed above these source lines SL. A plurality of word lines WL extending in the X direction are disposed between the memory cells MC arranged in the Y direction. In the select gate 110, a plurality of lower-layer wiring lines LIb extending in the Y direction are disposed. A plurality of select transistors ST are disposed above the plural lower-layer wiring lines LIb. A plurality of select gate lines SG extending in the X direction are disposed between the select transistors ST arranged in the Y direction. As regards the arrangement in the Y direction of the select transistors ST, for example, the select transistors ST are disposed at every second position in the X direction, and a dummy channel portion 5d is arranged therebetween.

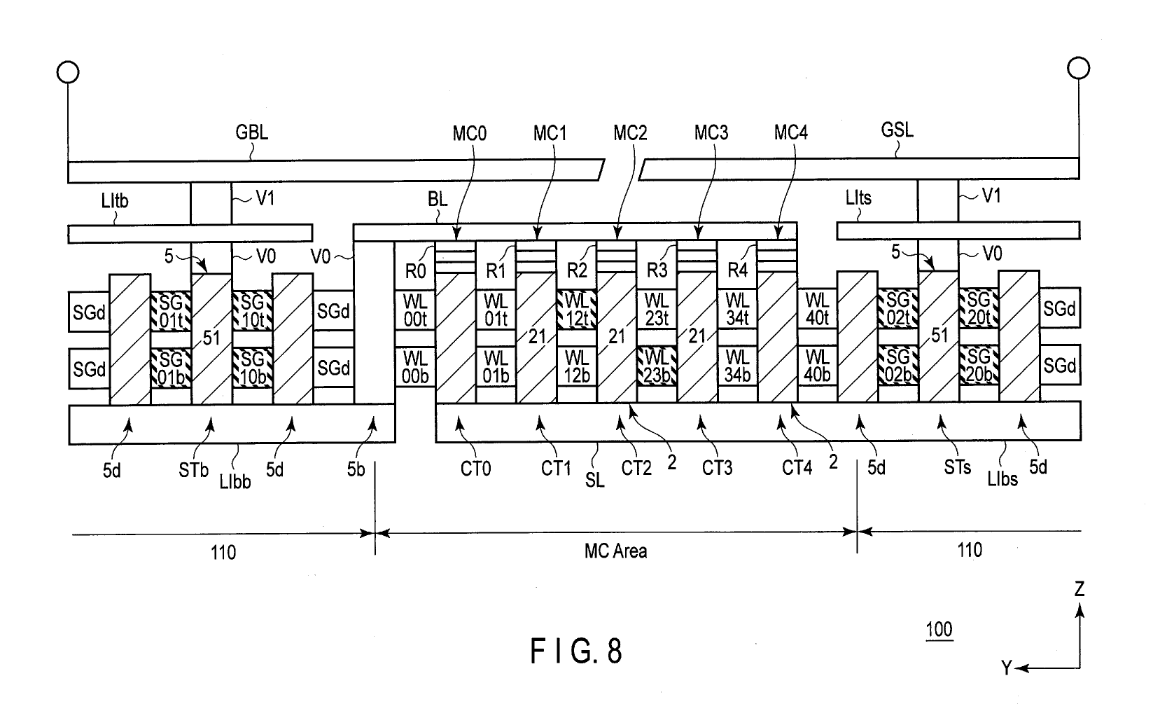

FIG. 8 schematically illustrates an example of a wiring structure between transistors in the present embodiment.

As illustrated in FIG. 8, a select transistor STb is disposed on one side of a plurality of memory cells MC via dummy gates SGd and a dummy channel portion 5d. The select transistor STb and the plural memory cells MC are connected via a connection portion 5b which is connected to, for example, a lower-layer wiring line LIbb and a bit line BL. The connection portion 5b has, for example, the same structure as the dummy channel portion 5d. The connection portion 5b and the bit line BL are connected via a contact V0. The select transistor STb and the global bit line GBL are connected via an upper-layer wiring line LItb, for example, by contacts V0, V1 provided above the select transistor STb. In this manner, a path connecting the memory cell MC and the global bit line GBL includes, in the named order, the bit line BL, the contact V0, the connection portion 5b, the lower-layer wiring line LIbb, the select transistor STb, the contact V0, the upper-layer wiring line LItb, and the contact V1. The upper-layer wiring line LItb, the lower-layer wiring line LIbb, the connection portion 5b, and the contacts V0, V1 connected thereto may be regarded as a part of the global bit line GBL.

On the other side of the plural memory cells MC, a select transistor STs is disposed via a dummy channel portion 5d. The plural memory cells MC and the select transistor STs are connected, for example, via a source line SL and a lower-layer wiring line LIbs. The select transistor STs and the global source line GSL are connected via an upper-layer wiring line LIts, for example, by contacts V0, V1 provided above the select transistor STs. In this manner, a path connecting the memory cell MC and the global source line GSL includes, in the named order, the source line SL, the lower-layer wiring line LIbs, the select transistor STs, the contact V0, the upper-layer wiring line LIts, and the contact V1. The upper-layer wiring line LIts, the lower-layer wiring line LIbs, and the contacts V0, V1 connected thereto may be regarded as a part of the global source line GSL.

In the meantime, in the configuration of FIG. 8, the upper-layer wiring lines LItb, LIts may be dispensed with, and each select transistor ST may be connected to each global wiring line via the contact V0, V1.

As has been described above, in the example of FIG. 8, each select transistor ST and each global wiring line are connected on an upper side by the contact V0, V1. Further, each select transistor ST and the memory cell MC are connected via the lower-layer wiring line LIb. At this time, the connection portion 5b is used as an auxiliary member which connects the lower-layer wiring line LIbb of the select transistor STb and the bit line BL above the memory cell MC.

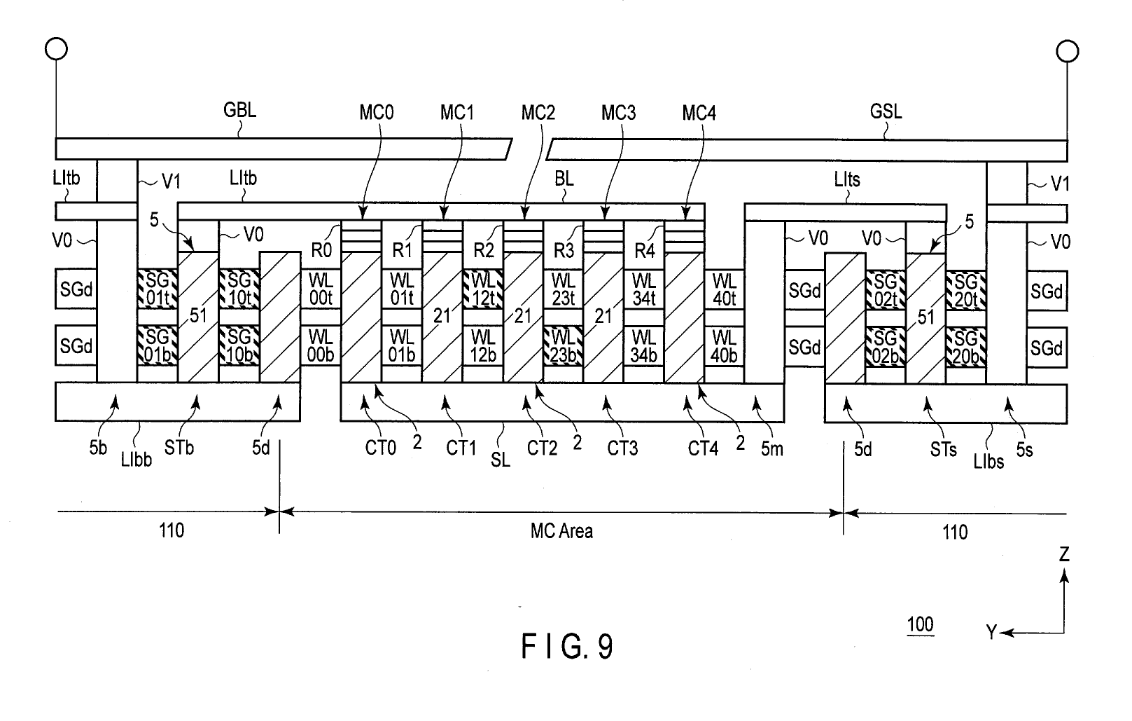

FIG. 9 schematically illustrates an example of another wiring structure between transistors in the present embodiment.

The example illustrated in FIG. 9 differs from the above-described example of FIG. 8 with respect to the connection mode between the plural memory cells MC and the select transistors STb, STs on both sides of the memory cells MC. Specifically, on one side of the plural memory cells MC, the select transistor STb is disposed via the dummy channel 5d. The select transistor STb and the plural memory cells MC are connected, for example, via the upper-layer wiring line LItb and the bit line BL. The select transistor STb and the global bit line GBL are connected, for example, via the connection portion 5b connected to the lower-layer wiring line LIbb, the upper-layer wiring line LItb, and the contacts V0, V1. In this manner, a path connecting the memory cell MC and the global bit line GBL includes, in the named order, the bit line BL, the upper-layer wiring line LItb, the contact V0, the select transistor STb, the lower-layer wiring line LIbb, the connection portion 5b, the contact V0, the upper-layer wiring line LItb, and the contact V1. The upper-layer wiring line LItb, the lower-layer wiring line LIbb, the connection portion 5b, and the contacts V0, V1 connected thereto may be regarded as a part of the global bit line GBL.

On the other side of the plural memory cells MC, the select transistor STs is disposed via dummy gates SGd and a dummy channel portion 5d. The plural memory cells MC and the select transistor STs are connected, for example, via a connection portion 5m which is connected to the source line SL and the upper-layer wiring line LIts. The select transistor STs and the global source line GSL are connected, for example, via a connection portion 5s connected to the lower-layer wiring line LIbs, the upper-layer wiring line LIts, and the contacts V0, V1. In this manner, a path connecting the memory cell MC and the global source line GSL includes, in the named order, the source line SL, the connection portion 5m, the contact V0, the upper-layer wiring line LIts, the contact V0, the select transistor STs, the lower-layer wiring line LIbs, the connection portion 5s, the contact V0, the upper-layer wiring line LIts, and the contact V1. The upper-layer wiring line LIts, the lower-layer wiring line LIbs, the connection portion 5m, 5s, and the contacts V0, V1 connected thereto may be regarded as a part of the global source line GSL.

In the meantime, in the configuration of FIG. 9, the upper-layer wiring lines LItb, LIts above the connection portions 5b, 5s may be dispensed with, and each connection portion 5b, 5s may be connected to each global wiring line by the contact V0, V1.

As has been described above, in the example of FIG. 9, each select transistor ST and each global wiring line are connected via the lower-layer wiring line LIb. At this time, the connection portion 5b, 5s is used as an auxiliary member which connects the lower-layer wiring line LIb and the upper global wiring line. Further, each select transistor ST and memory cell MC are connected via the upper-layer wiring line LIt. At this time, the connection portion 5m is used as an auxiliary member which connects the upper-layer wiring line LIts of the select transistor STs and the source line SL under the memory cell MC.

Aside from the examples illustrated in FIG. 8 and FIG. 9, the wiring structure between the memory cell MC and the select transistors STb, STs may be various combinational structures of the above-described wiring modes of the respective structural elements. Specifically, the present embodiment may adopt wiring structures of various combinations of, for example, the case in which a select transistor ST and a global wiring line are connected on an upper side by the contact V0, V1, the case in which a select transistor ST and a global wiring line are connected via the lower-layer wiring line Lib, the case in which a select transistor ST and memory cells MC are connected via the upper-layer wiring line LIt, and the case in which a select transistor ST and memory cells MC are connected via the lower-layer wiring line LIb. At this time, the connection portion 5b, 5s, 5m is used, where necessary, as an auxiliary member which connects an upper structural element and a lower structural element.

### (5) Operation of Resistance Change Type Memory Device

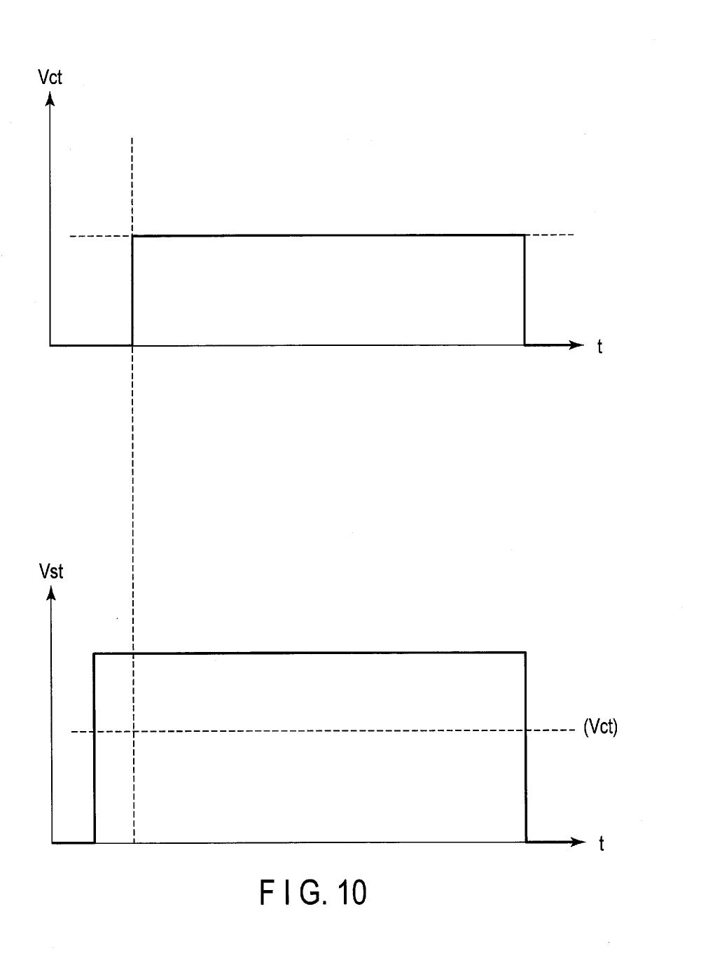

An operation example of the MRAM 10 is described by using FIG. 10A and FIG. 10B, while referring to FIG. 8 and FIG. 9. The operation below is executed by the select gate 110, the row decoders 150, the SA/WD 160, etc., in accordance with the control of the controller 190 of FIG. 1 which has received instructions from the outside.

In a read operation to a memory cell MC, one bit line BL is electrically connected to one sense amplifier 160sa of the SA/WD 160. Further, a source line SL, which is paired with this bit line BL, is connected to the current sink 130 and is set at a ground potential VSS. On the other hand, in a write operation, conversely, there is an another case besides the abovementioned case of the read operation, in which one source line SL is electrically connected to the SA/WD 160, and a bit line BL, which is paired with this source line SL, is connected to the current sink 130 and is set at the ground potential VSS. In the operation of write and read, the potential of the word line WL, which is connected to one memory cell MC of the memory cells MC connected to the above bit line BL and source line SL, is set at H level by the row decoder 150. Thereby, the one memory cell MC is electrically connected to the above bit line BL and source line SL.

By the above, a write current or read current is caused to flow to the memory cell MC from the SA/WD 160 via the bit line BL and the source line SL. Thereby, a write operation or a read operation is executed for the MTJ element R included in the memory cell MC.

In the above, the bit line BL and the SA/WD 160 or current sink 130 are electrically connected via the global bit line GBL. The bit line BL and the global bit line GBL are electrically connected by turn-on of the select transistor STb connected to this bit line BL. The source line SL and the SA/WD 160 or current sink 130 are electrically connected via the global source line GSL. The source line SL and the global source line GSL are electrically connected by turn-on of the select transistor STs connected to this source line SL. The bit line BL and the source line SL, and the memory cell MC, are electrically connected by turn-on of the cell transistor CT.

The following is a concrete example of the case in which a memory cell MC2 is selected in FIG. 8 and FIG. 9. In FIG. 8 and FIG. 9, word lines WL, to which an H level voltage is applied, are indicated by thick-line frames with hatching. Word lines WL, to which an L level voltage is applied, are indicated by thin-line frames without hatching.

As illustrated in FIG. 8 and FIG. 9, when the memory cell MC2 is selected, the select transistors STb, STs provided on the bit line BL and the source line SL, which are connected to the memory cell MC2, and the cell transistor CT2, which is included in the memory cell MC2, are turned on.

In the cell transistor CT2, a word line WL23b on one side of the first stage is activated, and a word line WL12t on the other side of the second stage is activated. Specifically, the word lines WL23b, WL12t are set at H level. The other word lines WL are set at L level. Thereby, the cell transistor CT2 is turned on.

By the activation of the word line WL23b, an inversion layer along the word line WL23b is formed near the word line WL23b in a lower part of the semiconductor layer 21 included in the cell transistor CT2. By the activation of the word line WL12t, an inversion layer along the word line WL12t is formed near the word line WL12t in an upper part of the semiconductor layer 21 included in the cell transistor CT2. Since the width in the Y direction of the channel portion 2 in the cell transistor CT2 is sufficiently small, the inversion layers formed in the lower part and upper part of the semiconductor layer 21 are connected to each other. Thereby, a continuous current path, which conducts with a lower end of an MTJ element R2 and the source line SL, is formed in the semiconductor layer 21. Thus, the cell transistor CT2 is turned on.

On the other hand, in the cell transistors CT other than the cell transistor CT2, the word lines WL are set at L level. Thus, the cell transistors CT other than the cell transistor CT2 are not turned on. For example, in the cell transistor CT1, the word line WL12t on one side of the second stage is activated, and an inversion layer is formed in the upper part of the semiconductor layer 21. However, each of word lines WL01b, WL12b of the first stage is set at L level, and no inversion layer is formed in the lower part of the semiconductor layer 21. Thus, a continuous current path, which conducts with a lower end of the MTJ element R1 and the source line SL, is not formed in the semiconductor layer 21, and the cell transistor CT1 is not turned on. In the cell transistor CT3, the word line WL23b on one side of the first stage is activated, and an inversion layer is formed in the lower part of the semiconductor layer 21. However, each of word lines WL23t, WL34t of the second stage is set at L level, and no inversion layer is formed in the upper part of the semiconductor layer 21. Thus, a continuous current path, which conducts with a lower end of the MTJ element R3 and the source line SL, is not formed in the semiconductor layer 21, and the cell transistor CT3 is not turned on

Like the above, in the select transistors STb, STs, too, select gate lines SG on one side of the first stage and select gate lines SG on the other side of the second stage are activated, and thereby these select transistors STb, STs can be turned on. However, in the select transistors STb, STs of the present embodiment, for example, all of the four select gate lines SG are activated.

Specifically, in the select transistor STb, select gate lines SG01b, SG10b, SG01t, SG10t on both sides of the channel portion 5 are activated. In other words, the select gate lines SG01b, SG10b, SG01t, SG10t are set at H level. Thereby, the select transistor STb is turned on.

By the activation of the select gate lines SG01b, SG10b, inversion layers are formed along the select gate lines SG01b, SG10b in the lower part of the semiconductor layer 51 included in the select transistor STb. These inversion layers are formed, for example, near the select gate lines SG01b, SG10b, respectively. Alternatively, if the width in the Y direction of the channel portion 5 is sufficiently small, one inversion layer is formed near the center in the Y direction of the semiconductor layer 51. By the activation of the select gate lines SG01t, SG10t, inversion layers are formed along the select gate lines SG01t, SG10t in the upper part of the semiconductor layer 51 included in the select transistor STb. These inversion layers are formed, for example, near the select gate lines SG01t, SG10t, respectively. Alternatively, if the width in the Y direction of the channel portion 5 is sufficiently small, one inversion layer is formed near the center in the Y direction of the semiconductor layer 51. The inversion layers formed in the lower part and upper part of the semiconductor layer 51 are connected to each other. Thereby, a continuous current path, which conducts with a lower end of the contact V0 and the lower-layer wiring line LIbb, is formed in the semiconductor layer 51. Thus, the select transistor STb is turned on.

In the select transistor STs, select gate lines SG02b, SG20b, SG02t, SG20t on both sides of the channel portion 5 are activated. Specifically, the select gate lines SG02b, SG20b, SG02t, SG20t are set at H level. Thereby, inversion layers are formed in the semiconductor layer 51 of the select transistor STs, and a continuous current path, which conducts with a lower end of the contact V0 and the lower-layer wiring line LIbs, is formed. Thus, the select transistor STs is turned on.

As described above, by the turn-on of the select transistor STb, the cell transistor CT2, and the select transistor STs, a current path extending from the global bit line GBL to the global source line GSL via the memory cell MC2 is formed.

In the example of FIG. 8, this current path extends from the global bit line GBL to the global source line GSL via the upper-layer wiring line LItb, the select transistor STb, the lower-layer wiring line LIbb, the connection portion 5b, the bit line BL, the MTJ element R2, the cell transistor CT2, the source line SL, the lower-layer wiring line LIbs, the select transistor STs, and the upper-layer wiring line LIts.

In the example of FIG. 9, this current path extends from the global bit line GBL to the global source line GSL via the connection portion 5b, the lower-layer wiring line LIbb, the select transistor STb, the upper-layer wiring line LItb, the bit line BL, MTJ element R2, the cell transistor CT2, the source line SL, the connection portion 5m, the upper-layer wiring line LIts, the select transistor STs, the lower-layer wiring line LIbs and the connection portion 5s.

In the write operation, the SA/WD 160 supplies a write current from the global bit line GBL to the global source line GSL via the memory cell MC2. Alternatively, the SA/WD 160 supplies a write current from the global source line GSL to the global bit line GBL via the memory cell MC2. The write current flows to the ground potential VSS via the current sink 130 to which the global bit line GBL or global source line GSL is connected. Thereby, the write operation is executed for the memory cell MC.

In the read operation, the SA/WD 160 supplies a read current from the global bit line GBL to the global source line GSL via the memory cell MC2. The read current flows to the ground potential VSS via the current sink 130 to which the global source line GSL is connected. Thereby, the read operation is executed for the memory cell MC.

An upper part of FIG. 10 schematically illustrates an example of a voltage value at a time of the operation of the cell transistor according to the present embodiment. A lower part of FIG. 10 schematically illustrates an example of a voltage value at a time of the operation of the select transistor according to the present embodiment.

The abscissa of FIG. 10 indicates an elapsed time (t) at a time when both the transistors CT, ST are turned on. In the upper and lower parts of FIG. 10, the time axes coincide. The ordinate of the upper part of FIG. 10 indicates a voltage value Vct which is applied to the cell transistor CT at the time of the operation of the cell transistor CT. The ordinate of the lower part of FIG. 10 indicates a voltage value Vst which is applied to the select transistor ST at the time of the operation of the select transistor ST.

As illustrated in FIG. 10, the application of the voltage to the select transistor ST is earlier than, for example, the application of the voltage to the cell transistor CT. Further, the voltage value Vct of the voltage applied to the cell transistor CT is less than, for example, the voltage value Vst of the voltage applied to the select transistor ST.

However, regardless of FIG. 10, the application of the voltage to the select transistor ST may be later than the application of the voltage to the cell transistor CT, or the timing of application of the voltage to the cell transistor CT may coincide with timing of application of the voltage to the select transistor ST. Further, the voltage value Vct may be greater than the voltage value Vst, or the voltage value Vct and the voltage value Vst may be equal.

### (6) Advantageous Effects of this Embodiment

According to the present embodiment, the following one or plural advantageous effects can be obtained.

(A) According to this embodiment, the cell transistor CT includes the channel portion 2, and the two-stage double-gates 3 which are disposed in two stages (sets), with the channel portion 2 being interposed. The select transistor STb, STs includes the channel portion 5, and the two-stage double-gates 3 which are disposed in two stages (sets), with the channel portion 5 being interposed. In this manner, since each transistor CT, STb, STs is constructed as a vertical transistor, each transistor CT, STb, STs can be reduced in size, and a higher integration density is realized.

(B) According to this embodiment, of the two-stage double-gates 3 of the cell transistor CT, at least the two-stage gates (word lines WL) on one side of the channel portion 2 are shared by another cell transistor CT neighboring this cell transistor CT. Thus, since the cell transistor CT has the double gate structure in which the gates are shared between the cell transistors CT, the cell transistor CT can be further reduced in size, and a higher integration density is realized.

An SGT (Surrounding Gate Transistor) is an example of the vertical transistor. The SGT includes a gate surrounding the periphery of the channel portion which extends in the Z direction. This gate is occupied by an individual SGT. It is thus expected that the processing of the gate becomes difficult, with a progress of microfabrication and an increase in integration density of the SGT. There is concern that this may become a hindrance to the progress of microfabrication and increase in integration density of the SGT.

According to this embodiment, the cell transistor CT is constructed as a gate-shared type transistor. Thereby, the cell transistor CT is reduced in size. With this cell transistor CT being used, a memory cell MC having, for example, an area of disposition of 4F² (2F×2F), where F is a minimum feature dimension, is realized.

(C) According to this embodiment, for example, when the cell transistor CT2 is to be turned on, among the two-stage double-gates 3, the word line WL23b on one side of the channel portion 2 of the first stage, is activated, and the word line WL12t on the other side of the channel portion 2 in the second stage is activated. Since this operation is executed in the cell transistor CT, the cell transistor CT can surely be turned on/off.

For example, if the vertical transistor is simply constructed to have a double-gate structure (of only one stage) in which gates are shared between neighboring vertical transistors, the following concern will arise. Specifically, if the gates on both sides of one vertical transistor are activated, a current for one gate, that is, about half the normal current (semi-select current), flows in the neighboring vertical transistor. The state of this vertical transistor is a state in which the vertical transistor is about to be half turned on, that is, a semi-selected state. Thus, if this vertical transistor is used, for example, as a cell transistor, it is possible that a memory cell MC, which is a target of operation, cannot correctly be selected.

According this embodiment, the cell transistor CT has a two-stage double-gate structure. In this cell transistor CT, the word lines WL, which are located at obliquely crossing positions of the first stage and the second stage, with the channel portion 2 being interposed, are activated. Thereby, the neighboring other cell transistor CT is suppressed from entering the semi-selected state, and the operational capability of the cell transistor CT is improved.

(D) According to this embodiment, when the select transistor ST is to be turned on, the select gate lines SG on both sides of the channel portion 5 in the first stage and second stage of the two-stage double-gates 6 are activated.

The number of select cell transistors ST is less than the number of cell transistors CT, and an increase in integration density is not so required for the select transistors ST as for the cell transistors CT. Thus, the gates of the select transistor ST are not shared between the select transistors ST, and are occupied by the individual select transistor ST. In this structure, when the select transistor ST is to be turned on, for example, all of the gates in the select transistor ST can be activated.

Thereby, firmer inversion layers are formed in the channel portion 5 of the select transistor ST. Thus, when the select transistor ST is turned on, the current value of, e.g. a write current flowing via the select transistor ST increases. In short, the current driving power of the select transistor ST is improved.

Further, no select gate line SG of L level exists around the select transistor ST that is turned on. Thus, for example, it is possible to suppress the flow of current through the select transistor ST from being hindered by the select gate line SG of L level. Therefore, by this, too, the current driving power of the select transistor ST is improved.

Since the current driving power of the select transistor ST is improved, as described above, a sufficient write current is supplied to the MTJ element R. Therefore, data can be more exactly be written in the MTJ element R.

(E) According this embodiment, there are provided the cell transistor CT which includes the two-stage double-gates 3 and is connected in series to the MTJ element R, and the select transistor ST which includes the two-stage double-gates 6 and is configured to electrically connect the local wiring line to the global wiring line.

In this manner, the MRAM 10 adopts at least either the hierarchical bit line method or the hierarchical source line method. Thereby, compared to the case in which neither the hierarchical bit line method nor the hierarchical source line method is adopted, the number of memory cells MC which are connected in parallel, as viewed from the SA/WD 160, is reduced. Thus, the total amount of leak current from the memory cells MC decreases. Further, a greater number of memory cells MC can be made to belong to one SA/WD 160, and an increase in integration density is realized.

Further, in this manner, since the select transistor STb, STs has the two-stage double-gate structure, like the cell transistor CT, the fabrication of the transistor CT, STb, STs becomes easier, and the fabrication process thereof can be simplified. Thus, the manufacturing cost can be reduced.

However, when the MRAM 10 adopts the hierarchical bit line method and the hierarchical source line method, three transistors (transistors CT, STb, STs) of the two-stage double-gate structure are connected in the current path extending from the SA/WD 160 to the current sink 130 via one memory cell MC. Even in this case, in the select transistor STb, STs, the gates are not shared between the neighboring transistors, and the two-stage select gates on both sides of the channel portion 5 are activated. Thus, a sufficient current driving power is obtained by the transistors CT, STb, STs, as a whole, and the precision of write in the memory cell MC can be improved.

In this manner, in the MRAM 10 of the hierarchical bit line method and the hierarchical source line method, the semi-select current can be suppressed in the cell transistors CT which are integrated with high density.

Further, the current driving power can be improved in the select transistors STb, STs, for which higher integration is not so required as for the cell transistors CT.

(F) According to this embodiment, the select gate 110 includes the dummy channel portions 5d and the dummy gates SGd. Thereby, the arrangement pattern of the select transistors ST, etc. in the select gate 110 becomes similar to the arrangement pattern of memory cells MC in the memory cell MC region. Thus, at the time of manufacture of the transistors and at the time of operation of the transistors, the position dependency between the transistors can be suppressed. Specifically, at the time of manufacture of the transistors, the processing characteristics for the transistors CT, ST tend to easily become uniform. It is also easy to form the transistors CT, ST together. Further, at the time of operation of the transistors, the operational characteristics of these transistors CT, ST tend to become uniform.

(G) According to this embodiment, the cell transistors CT and the select transistors STb, STs are connected by properly using the upper-layer wiring lines LIt, lower-layer wiring lines LIb, connection portions 5b, 5s, 5m, and the contacts V0, V1 connected thereto. Thereby, various wiring structures can be adopted between the transistors CT, STb, STs. Thus, the layout design of the MRAM 10 becomes easier.

(H) According to this embodiment, the application of the voltage to the select transistor ST is earlier than the application of the voltage to the cell transistor CT. Thereby, the timing of turn-on of each transistor CT, ST can be made uniform.

When one memory cell MC is selected, it is desirable that the respective transistors CT, ST, which are connected to the memory cell MC, be turned on, for example, at the same time. Thereby, the time until the selection of the memory cell MC is shortened, and the operation of write and read for the memory cell MC is executed in a shorter time.

As described above, the number of select gate lines SG, to which a voltage is applied when the select transistor ST is turned on, is greater than, for example, the number of word lines WL, to which a voltage is applied when the cell transistor CT is turned on. Thus, there is a case in which the time from the application of voltage to turn-on of the select transistor ST is longer than the time from the application of voltage to turn-on of the cell transistor CT. By making the timing of application of the voltage to the select transistor ST earlier than the timing of application of the voltage to the cell transistor CT, it becomes possible to make such adjustment that, for example, the respective transistors CT, ST are turned on at the same time.

(I) According to this embodiment, the voltage value Vct of the voltage applied to the cell transistor CT is less than the voltage value Vst of the voltage applied to the select transistor ST. The number of cell transistors CT is greater than the number of select transistors ST, and there is a case in which the ratio of occurrence of defects, such as an electrostatic defect, in the cell transistors CT is high. By making the voltage value Vct relatively small, the ratio of occurrence of defects of the cell transistors CT can be reduced. As a standard at this time, the voltage value Vct can be made smaller than, for example, the voltage value Vst.

### Second Embodiment

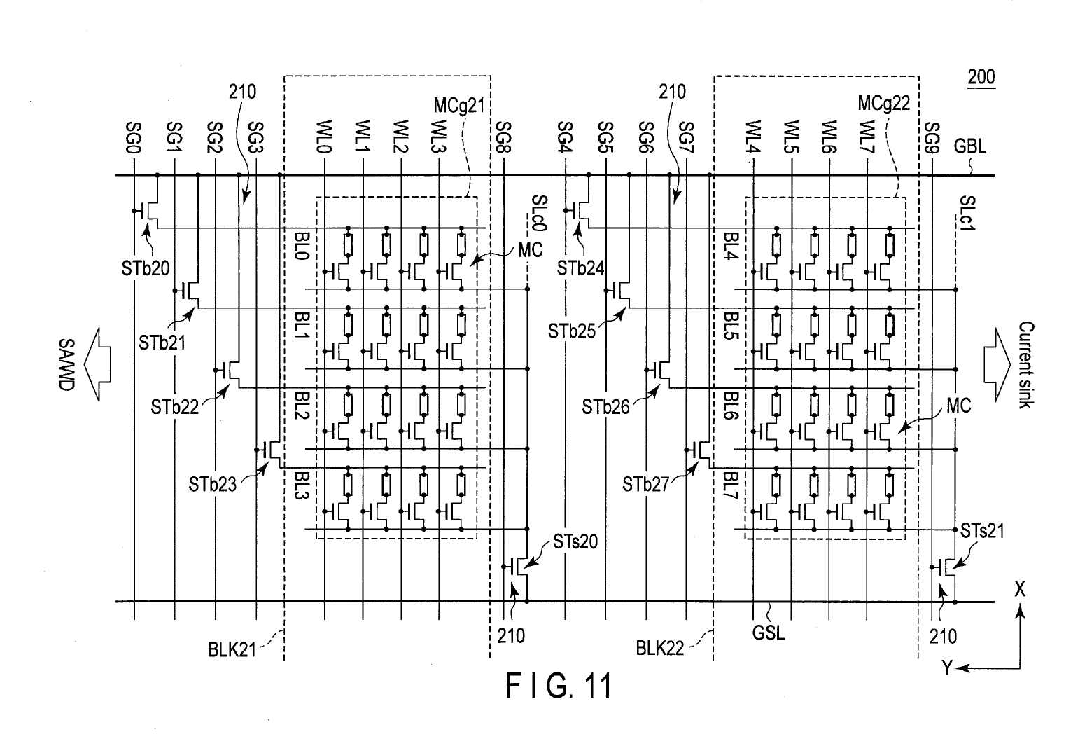

The present embodiment is described with reference to FIG. 11 to FIG. 14. An MRAM 20 of this embodiment differs from the above-described embodiment in that a source line SLc is not separated.

### (1) Circuit Configuration Example of Resistance Change Type Memory Device

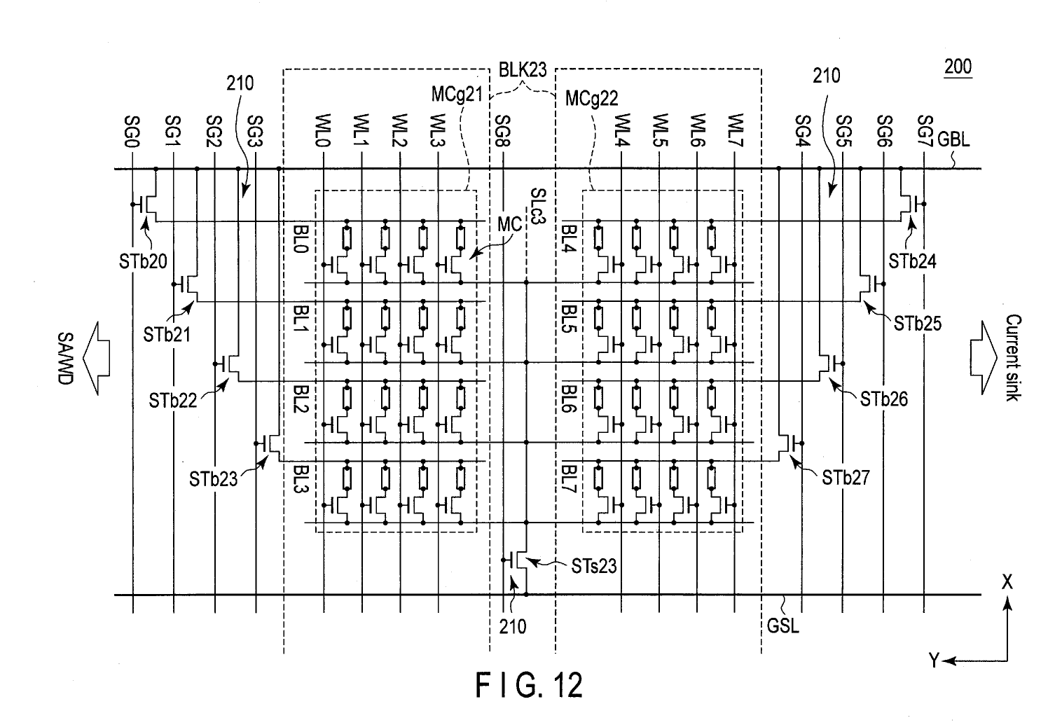

Referring to FIG. 11 and FIG. 12, an example of the circuit configuration of the MRAM 20 is described. Each transistor CT, STb, STs of the MRAM 20 has, for example, a two-stage double-gate structure. In the cell transistors CT, such gates are shared between neighboring transistors. In FIG. 11 and FIG. 12, the transistors CT, STb, BT are illustrated in a simplified manner as in the right parts of FIG. 3A and FIG. 3B.

FIG. 11 illustrates an example of the circuit configuration of the memory cell array of the memory device according to the present embodiment.

As illustrated in FIG. 11, the MRAM 20 includes a global bit line GBL serving as a global wiring line, and a global source line GSL serving as a global wiring line which is paired with the global bit line GBL. Memory cell groups MCg21, MCg22, in which a plurality of memory cells MC are arranged in a matrix, are included between the global bit line GBL and the global source line GSL.

In the memory cell group MCg21, a plurality of memory cells MC, which are arranged in the X direction, are commonly connected to a word line WL (WL0 to WL3). A plurality of memory cells MC, which are arranged in the Y direction, are commonly connected to a bit line BL (BL0 to BL3) functioning as a local wiring line. These plural memory cells MC arranged in a matrix are connected to a common source line SLc0. Each bit line BL is connected to the global bit line GBL via a select transistor STb (STb20 to STb23) functioning as a first select transistor. The source line SLc0 is connected to the global source line GSL via a select transistor STs20 functioning as a second select transistor. The gate, functioning as a control node, of the select transistor STb (STb20 to STb23) is connected to a select gate line SG (SG0 to SG3). The gate, functioning as a control node, of the select transistor STs20 is connected to a select gate line SG8.

In the memory cell group MCg22, a plurality of memory cells MC, which are arranged in the X direction, are commonly connected to a word line WL (WL4 to WL7). A plurality of memory cells MC, which are arranged in the Y direction, are commonly connected to a bit line BL (BL4 to BL7) functioning as a local wiring line. These plural memory cells MC arranged in a matrix are connected to a common source line SLc1. Each bit line BL is connected to the global bit line GBL via a select transistor STb (STb24 to STb27) functioning as a first select transistor. The source line SLc1 is connected to the global source line GSL via a select transistor STs21 functioning as a second select transistor. The gate, functioning as a control node, of the select transistor STb (STb24 to STb27) is connected to a select gate line SG (SG4 to SG7). The gate, functioning as a control node, of the select transistor STs21 is connected to a select gate line SG9.

The above-described select transistors STb and select transistors STs are included in a select gate 210.

By the above, a current path is constituted from the global bit line GBL to the global source line GSL via the bit line BL, the memory cell MC, and the source line SLc.

Specifically, in the memory cell group MCg21, any one of the plural select transistors STb (STb20 to STb23) and the select transistor STs20 are turned on, and thereby one bit line BL is electrically connected to the global bit line GBL, and the source line SLc0 is electrically connected to the global source line GSL. Furthermore, any one of the word lines WL (WL0 to WL3) is set at H level, and thereby the cell transistor CT, which is connected to this word line WL, is turned on and one memory cell MC is selected.

In the memory cell group MCg22, any one of the plural select transistors STb (STb24 to STb27) and the select transistor STs21 are turned on, and thereby one bit line BL is electrically connected to the global bit line GBL, and the source line SLc1 is electrically connected to the global source line GSL. Furthermore, any one of the word lines WL (WL4 to WL7) is set at H level, and thereby the cell transistor CT, which is connected to this word line WL, is turned on and one memory cell MC is selected.

The memory cell group MCg21 and the memory cell group MCg22 are connected to different select transistors STb and select transistors STs, and constitute parts of different blocks BLK21, BLK22, respectively. Specifically, one block BLK includes a set of plural memory cells MC which are disposed, with plural word lines WL being shared between the select transistors STb and the select transistor STs which is paired with these select transistors STb. The one select transistor STs, which, together with the select transistors STb, sandwiches the plural memory cells MC connected commonly to the plural word lines WL, functions as a block gate transistor which partitions one block BLK.

FIG. 12 illustrates an example of another circuit configuration of the memory cell array of the memory device according to present embodiment.

The example illustrated in FIG. 12 differs from the example of FIG. 11 in that the memory cell groups MCg21, MCg22 share one source line SLc3. The memory cell groups MCg21, MCg22 are included in the same block BLK23. A select transistor STs23 functions as a block gate transistor which partitions the block BLK 23.

In the circuit configurations of FIG. 11 and FIG. 12, select transistors STb, STs may be included in one block BLK.

### (2) Configuration Example of Memory Cell Array

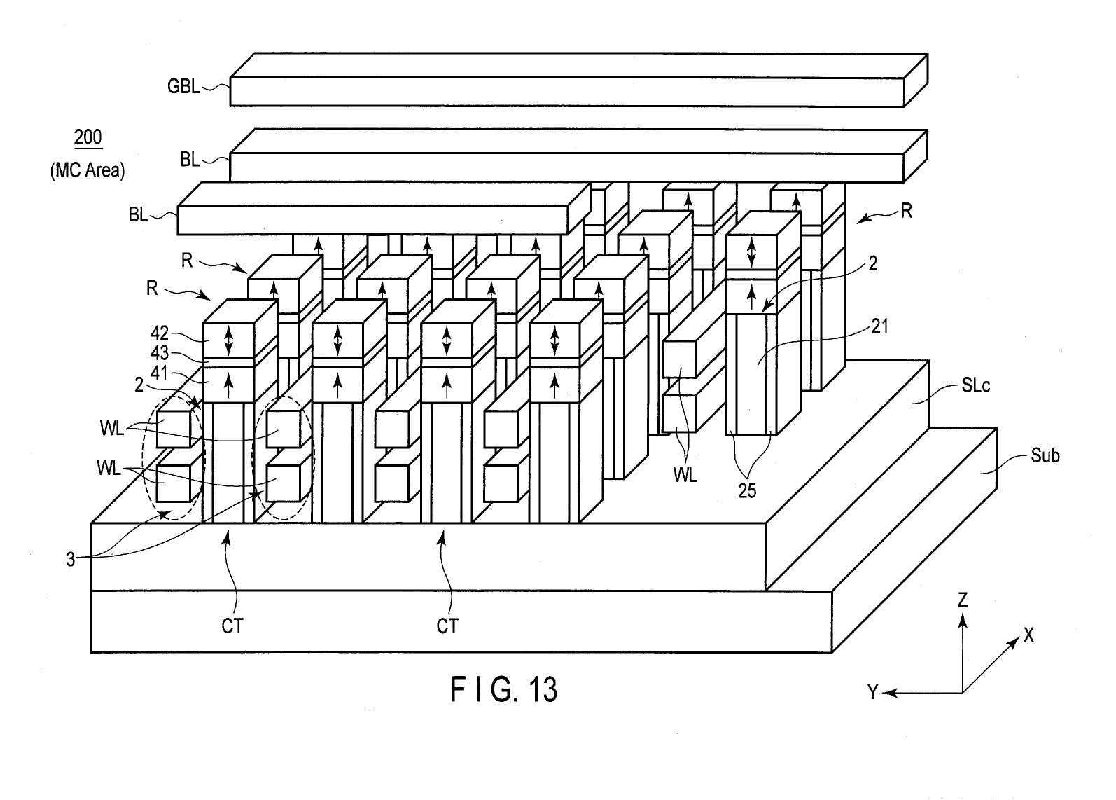

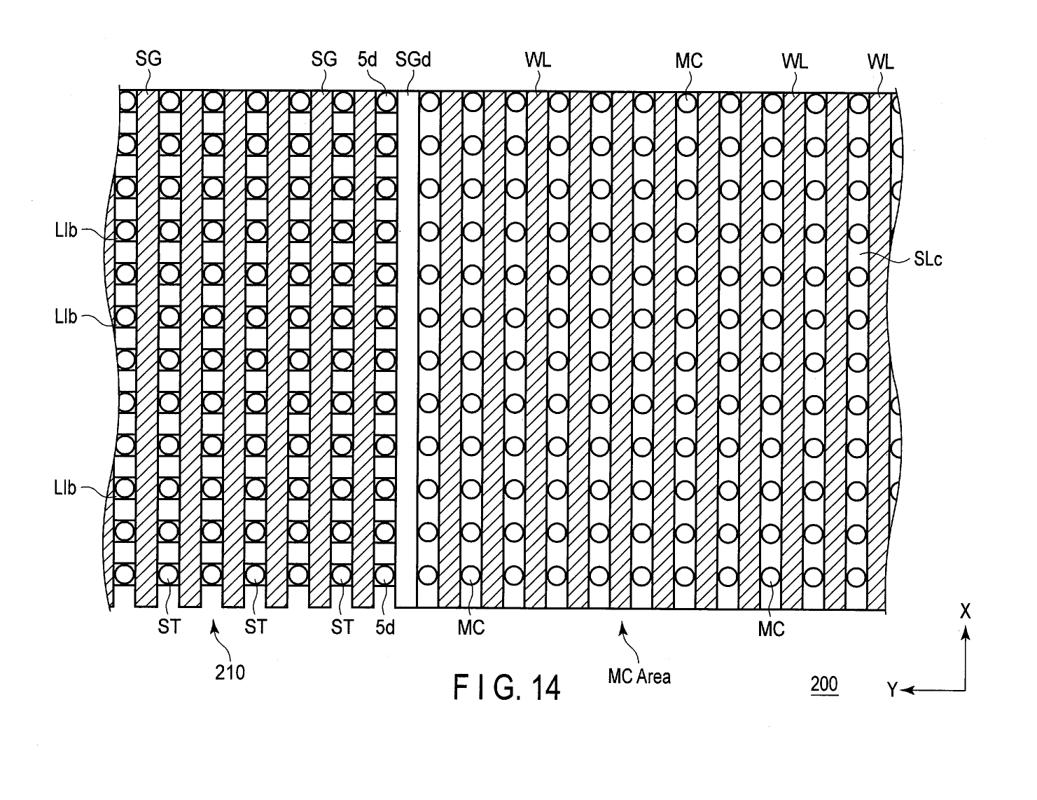

Referring to FIG. 13 and FIG. 14, a description is given of a configuration example of a memory cell array 200 of the MRAM 20.

FIG. 13 schematically illustrates a configuration example of the memory cell array of the memory device according to the present embodiment. FIG. 13 illustrates, in particular, a memory cell MC region in the memory cell array 200.

As illustrated in FIG. 13, in the memory cell MC region, a source line SLc is disposed above in the Z direction of the substrate Sub. In this embodiment, the source line SLc is not separated, for example, in the X direction. The plural cell transistors CT arranged in a matrix are commonly connected to the source line SLc. In this manner, the MRAM 20 has a memory cell array structure of a source line-shared type.

The source line SLc may contain the same kind of material as the substrate Sub as a main component, such as silicon (Si), polysilicon (Poly-Si), or tungsten (W). The source line SLc may be formed by processing a part of the substrate Sub. When the source line SLc contains, for instance, silicon as a main component, the source line SLc may be formed by diffusing impurities in a part of the substrate Sub.

FIG. 14 schematically illustrates a layout of the memory cell array of the memory device according to the present embodiment. In FIG. 14, the select transistors STb, STs are not distinguished.

As illustrated in FIG. 14, in the memory cell array 200, the source line SLc is not separated, and is disposed, for example, over the entirety of the memory cell MC region. In the select gate 210, a plurality of lower-layer wiring lines LIb, which are separated in the X direction, extend in the Y direction. However, the lower-layer wiring line disposed in the select gate 210 may partly include a region where the lower-layer wiring line is not separated, that is, may be a lower-layer wiring line of a partly shared type.

### (3) Operation of Resistance Change Type Memory Device

The MRAM 20 has, for example, the same block configuration as in FIG. 1. The operation of the MRAM 20 is mainly executed by the select gate 210, row decoders 150, SA/WD 160, etc., in accordance with the control of the controller 190 as shown in FIG. 1.

The select transistor STb, which is connected to one bit line BL, is turned on. Thereby, the bit line BL and the global bit line GBL are electrically connected. By turn-on of the select transistor STs, the source line SLc and the global source line GSL are electrically connected. The potential of the word line WL, which is connected to one memory cell MC of the memory cells MC connected to the above bit line BL, rises to H level. Thereby, the cell transistor CT in the memory cell MC is turned on, and the memory cell MC that is the target of operation is electrically connected to the bit line BL and the source line SL.

In this manner, in this embodiment, the memory cell MC is selected solely by selecting any one of the bit lines BL and any one of the word lines WL.

In this embodiment, too, in the cell transistor CT, the word lines WL, which are located at obliquely crossing positions of the first stage and the second stage, with the channel portion 2 being interposed, are activated. In the select transistor ST, the select gate lines SG of the two stages on both sides of the channel portion 5 are activated.

The other points of the MRAM 20 are the same as in the above-described embodiment.

In this embodiment, too, the same advantageous effects as in the above-described embodiment are obtained.

Further, according to this embodiment, the MRAM 20 has the source line-shared type memory cell array structure, in which the source line SLc is not separated. Thereby, the manufacture of the MRAM 20 becomes easier.

### Third Embodiment

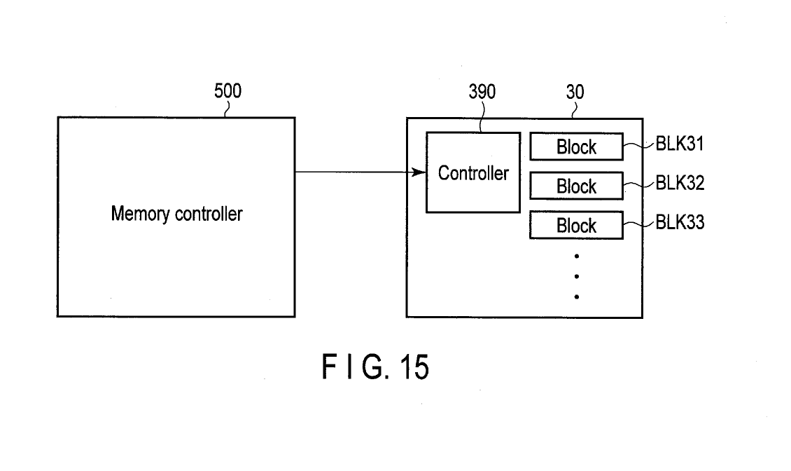

The present embodiment is described with reference to FIG. 15 to FIG. 18. An MRAM 30 of this embodiment stores block information of a block in which a defect occurred. The other structure of the MRAM 30 is the same as, for example, the above-described embodiment.

Specifically, the MRAM 30 may include, for example, the same circuit configuration as in the above-described FIG. 4, FIG. 11 or FIG. 12. The MRAM 30 may include, for example, the structure of FIG. 6A and FIG. 6B, or FIG. 13. The operation of the MRAM 30 may include, for example, the operation illustrated in FIG. 8 or FIG. 9.

Defects occurring in the block BLK include, for example, a formation defect of wiring between memory cells MC, or a short-circuit defect between memory cells MC due to foreign matter, etc. The MRAM 30 stores, for example, position information of a block BLK in which a defect occurred.

As in the above-described embodiment, each block BLK is partitioned by the select transistor STb and the select transistor STs paired with this select transistor STb. The information of a bad block, a block BLK in which a defect occurred, is stored in the MRAM 30, and thereby, for example, this block BLK is electrically isolated from the global wiring line, so that this block BLK may not be used.

A description will be given below of a method of isolating the block BLK in which a defect occurred, based on the block information.

### (1) Block Configuration Example of Resistance Change Type Memory Device

FIG. 15 illustrates an example of a block configuration of a memory device and a memory controller according to the present embodiment.

As illustrated in FIG. 15, a controller 390 of the MRAM 30 is connected to, for example, an external memory controller 500. In accordance with an instruction from the memory controller 500, the controller 390 executes an operation of write, read and erase. Further, the controller 390 stores block information. The block information is information relating to a plurality of blocks BLK (BLK31, BLK32, BLK33, . . . ) included in the MRAM 30. The other block configuration of the MRAM 30 is, for example, the same as the block configuration of FIG. 1.

The memory controller 500 executes operations, for example, based on instructions from an application in the memory controller 500, or instructions from a host device. The memory controller 500 transmits write data to the controller 390, and receives read data from the controller 390. In addition, the memory controller 500 reads, for example, block information which is stored in the controller 390, and executes mapping of the blocks BLK included in the MRAM 30 by using the block information.

The other points of the MRAM 30 are the same as in the above-described embodiment.

### (2) Configuration Example of Block Addresses

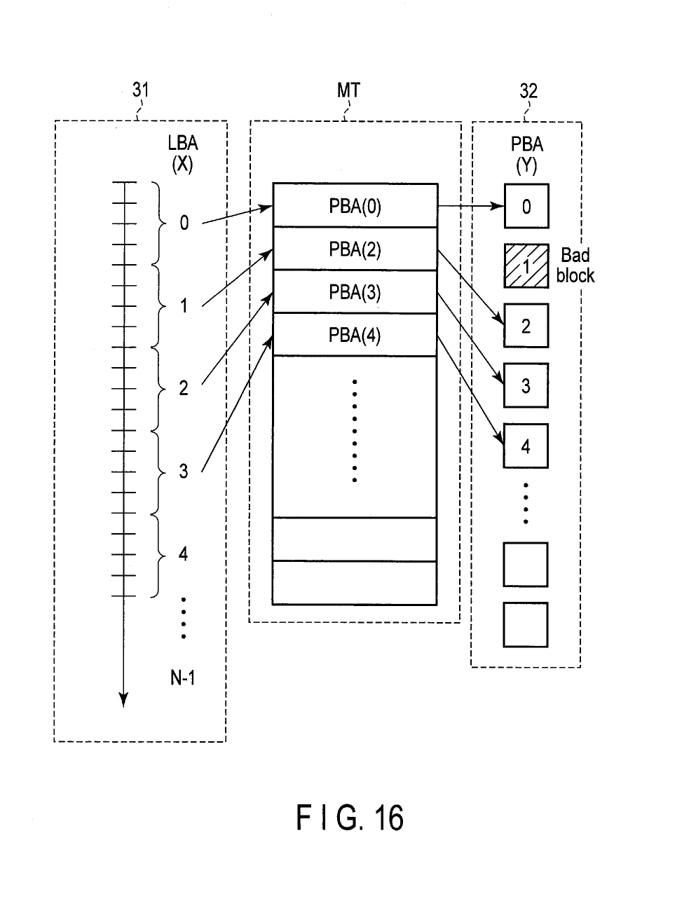

FIG. 16 schematically illustrates an example of mapping of blocks of the memory device according to the present embodiment.

As illustrated in FIG. 16, a logical address space 31 includes logical addresses LBA (X=1, 2, 3, . . . , N−1). A physical block 32 includes physical addresses PBA (Y=1, 2, 3, . . . ).

The logical address LBA is an address which is used by the application in the memory controller 500 or by the host device. Specifically, the application or host device identifies data of an operation target, based on the logical address. The physical address PBA is an address which identifies the block BLK of the MRAM 30, and is an address which is recognized by the controller 390.

A mapping table MT indicates the relationship in correspondency between the logical addresses LBA and the physical addresses PBA of plural blocks BLK. Each entry in the mapping table MT corresponds to one logical address LBA, and stores a physical address PBA which is associated with this logical address LBA.

The memory controller 500 manages, with use of the mapping table MT, the relationship in correspondency between each logical address LBA and the physical address PBA of the block BLK which stores data to which this logical address LBA is added.

The memory controller 500 executes mapping between the logical addresses LBA and the physical addresses PBA, by using the mapping table MT and the block information. For example, the memory controller 500 is instructed to write data, to which a certain logical address LBA is added, in the MRAM 30. In accordance with this instruction, the memory controller 500 instructs the controller 390 to write this logical address LBA into the block BLK having a certain physical address PBA. In addition, the memory controller 500 reflects on the mapping table MT the relationship in correspondency between a logical address LBA of data, the write of which has been instructed, and a physical address PBA which stores data to which this logical address LBA is added.

The memory controller 500 writes the mapping table MT in the MRAM 30, for example, before the MRAM 30 is powered off. For example, after the MRAM 30 is powered on, the memory controller 500 reads out the mapping table MT from the MRAM 30.

### (3) Example of Mapping Operation of Blocks

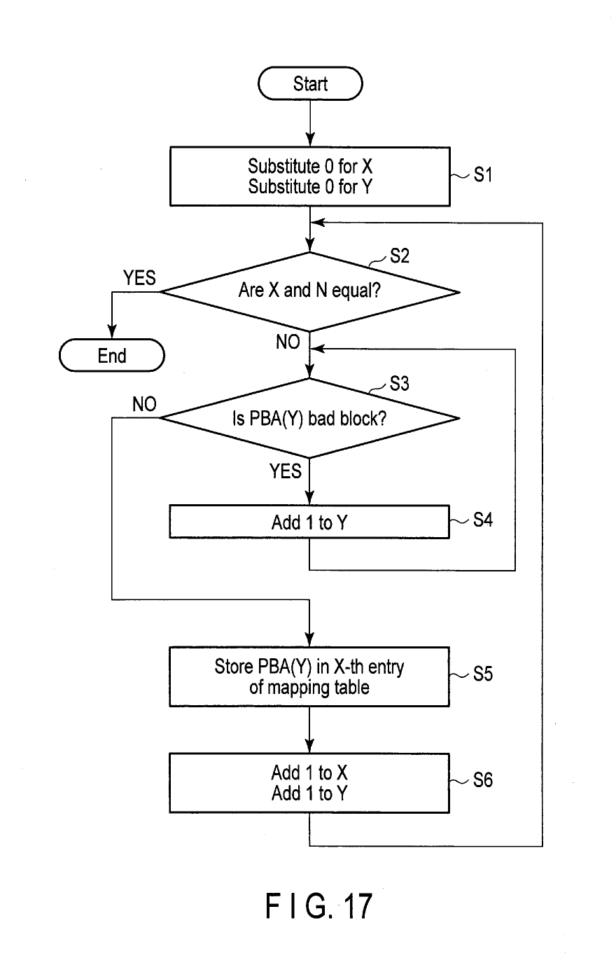

FIG. 17 illustrates a flow of the mapping operation of blocks of the memory device according to the present embodiment.

As illustrated in FIG. 16 and FIG. 17, based on the block information stored in the controller 390, the memory controller 500 allocates a physical address PBA of a valid block, a block in which no defect occurs, to a logical address LBA, and stores them in the mapping table MT. The following operation is executed mainly by the memory controller 500.

Specifically, by the memory controller 500, “0” is substituted for X and Y, respectively (step S1). Thereby, a number X of a logical address LBA (X) and a number Y of a physical address PBA (Y) are reset.

Next, it is determined whether X and N are equal or not (step S2). If X and N are not equal, it is determined that there remains a logical address LBA (X) to which a physical address PBA is to be allocated, and it is determined whether a physical address PBA (Y), which is in the processing order, is a bad block BLK or not (step S3). The determination as to whether the physical address. PBA (Y) is a bad block BLK or not is executed based on the block information which is stored in the controller 390.

If the physical address PBA (Y) is a bad block BLK, 1 is added to Y, without the physical address PBA (Y) being stored in the mapping table MT (step S4), and the determination of the next physical address PBA is executed (step S3). As illustrated in FIG. 16, for example, when a physical address PBA (1) is a bad block BLK, the physical address PBA (1) is not stored in the mapping table MT.

If the physical address PEA (Y) is not a bad block BLK, the physical address PBA (Y) is stored in an X-th entry of the mapping table MT (step S5), and 1 is added to X and Y, respectively.

The operation from step S2 to step S6 is repeated until X becomes N−1.

By the above, the valid blocks BLK, excluding the bad block BLK, are stored in the respective entries of the mapping table MT.

Referring to this mapping table MT, the memory controller 500 sends to the controller 390 the instructions for operations of write, read and erase, together with the physical address PBA of the block BLK that is the operation target. The physical address PBA of the bad block BLK is not stored in the mapping table MT, and does not become the operation target of write, read and erase. Specifically, at least at the time of operation of write, read and erase, the select transistors STb, STs of the bad block BLK are turned off, and the bad block BLK is electrically isolated from the global wiring lines.

The operation of the memory controller 500 illustrated in FIG. 17 is executed, for example, when it has become necessary to allocate a physical address PBA to a new logical address LBA. Specifically, the memory controller 500 stores already allocated values of X and Y, and executes step S6 at a time of allocating a physical address PBA to a new logical address LBA.

### (4) Number of Valid Blocks of Resistance Change Type Memory Device

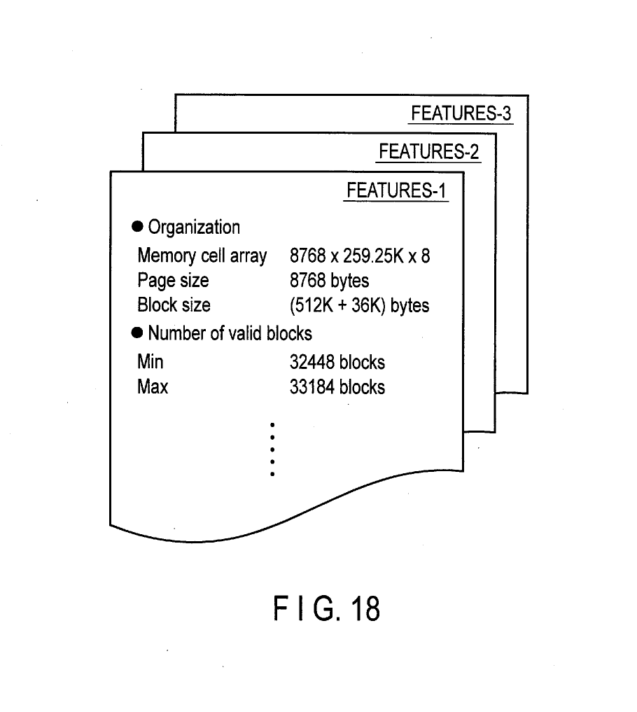

FIG. 18 illustrates a part of items described in a specification of the memory device according to the present embodiment.

As illustrated in FIG. 18, the specification of the MRAM 30 includes, for example, categories of “Organization” and “Number of valid blocks”.

The category of “Organization” includes, for example, items of “Memory cell array”, “Page size”, and “Block size”.

In the item of “Memory cell array”, information relating to the number of memory cells MC included in the MRAM 30 is described. In the item of “Page size”, the amount of data, which the page buffer 170 as shown in FIG. 1 stores at a write time and a read time, is described. In the item of “Block size”, the number of memory cells MC included in each block BLK is converted to a data bit number and described.

The category of “Number of valid blocks” includes, for example, items of “Minimum value” and “Maximum value”.

In the item of “Minimum value”, the minimum value of the number of valid blocks, which is guaranteed as specifications by the MRAM 30, is described. In the item of “Maximum value”, the maximum value of the number of valid blocks, which is guaranteed as specifications by the MRAM 30, is described. In this manner, in the specification of the MRAM 30, the limited numbers of valid blocks are defined.

Incidentally, the numerical values of the respective items shown in FIG. 18 are merely examples.

### (5) Advantageous Effects of this Embodiment

According to the present embodiment, other than the advantageous effects of the above-described embodiment, the following one or plural advantageous effects are obtained.

(A) According to this embodiment, the controller 390 stores information of a block BLK in which a defect occurred, among a plurality of blocks BLK. Thereby, for example, based on the block information of the controller 390, the mapping table MT is created, and a bad block BLK can be excluded from operation targets.

(B) According to this embodiment, when a write operation, a read operation and an erase operation are performed for the memory cells MC, a block BLK in which a defect occurred is in a state of electrical isolation from the global bit line GBL and the global source line GSL.

The block BLK is partitioned by the select transistors STb, STs. Thus, by turning off the select transistors STb, STs, the block BLK can be electrically isolated from the global bit line GBL and the global source line GSL. In short, the block BLK is a minimum unit which can be electrically isolated at a time of an operation of write and read.

At the time of write and read, by keeping the select transistors STb, STs of the bad block BLK in the OFF state, it is possible to make such a choice that the bad block BLK is not electrically connected to the global bit line GBL and the global source line GSL, that is, the bad block BLK is not selected or used. Thereby, the influence of, for instance, a short-circuit defect etc. between memory cells MC, can be confined within the bad block BLK.

In this manner, by limiting the number of valid blocks by setting a block BLK as one unit, it becomes possible to efficiently manage and control a location at which a defect occurred. Thereby, the number of valid memory cells can be suppressed from unnecessarily decreasing, and the number of valid memory cells increases.

### Fourth Embodiment

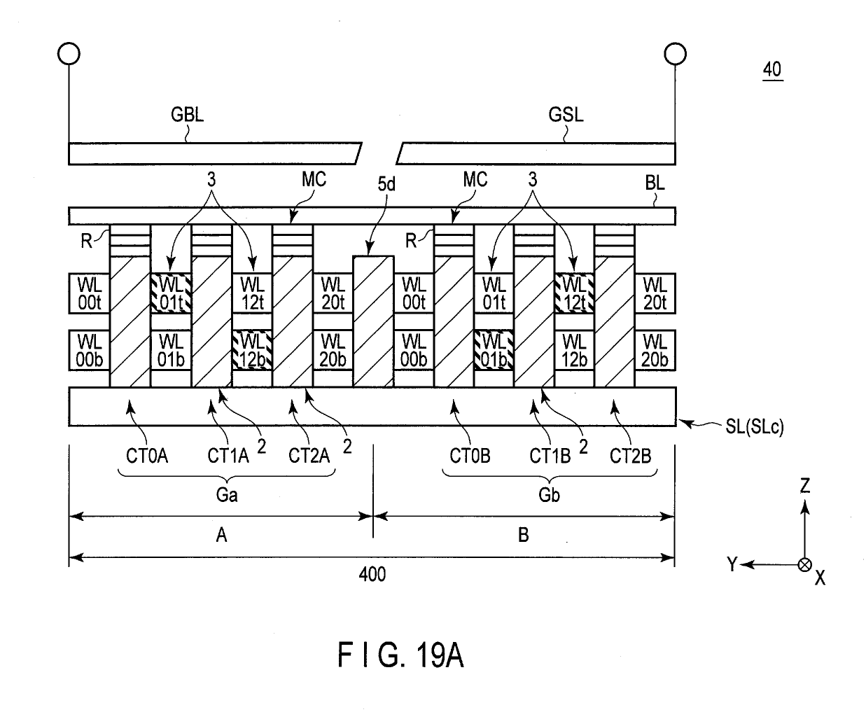

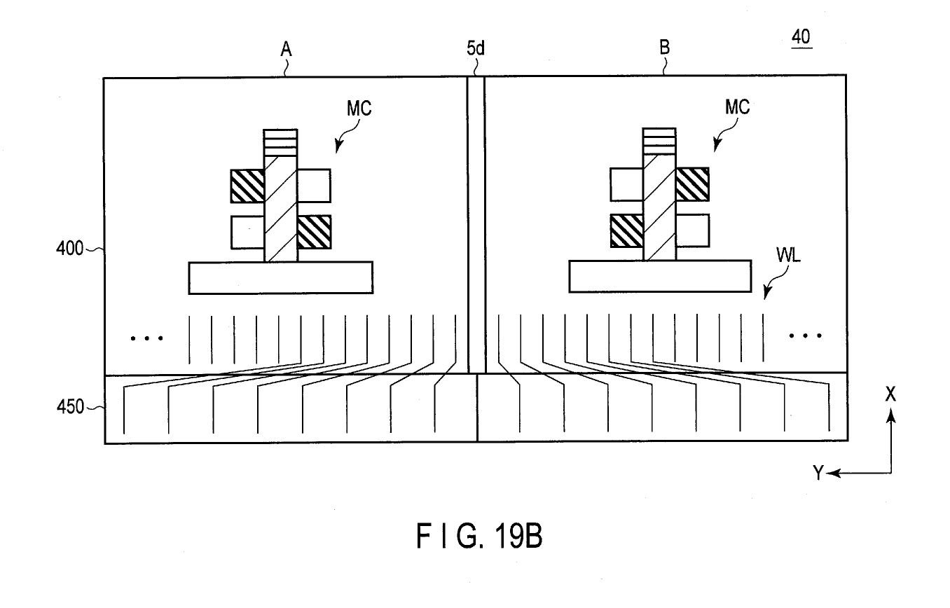

The present embodiment is described with reference to FIG. 19A and FIG. 19B. An MRAM 40 of this embodiment differs from the above-described embodiment in that the cell transistors CT are divided into a plurality of groups in which word lines WL that are operation targets are different.

FIG. 19A schematically illustrates an example of the operation of the memory device according to the present embodiment. FIG. 19B schematically illustrates a layout of a memory cell array and a row decoder of the memory device according to the present embodiment.

As illustrated in FIG. 19A, a memory cell array 400 of the MRAM 40 is divided into two areas A and B by a dummy channel portion 5d extending in the X direction. Of the memory cells MC in the memory cell array 400, the memory cells MC disposed in the area A belong to a first group Ga, and the memory cells MC disposed in the area B belong to a second group Gb.

When the cell transistor CT is turned on, the directions of activated word lines WL are opposite between the cell transistor CT included in the memory cell of the first group Ga and the cell transistor CT included in the memory cell of the second group Gb.

Specifically, when a cell transistor CT1A included in the first group Ga is turned on, for example, among the two-stage double-gates 3, a word line WL12b on one side of the channel portion 2 in the first stage, is activated, and a word line WL01t on the other side of the channel portion 2 in the second stage is activated.

When a cell transistor CT1B included in the second group Gb is turned on, for example, among the two-stage double-gates 3, a word line WL12t on one side of the channel portion 2 in the second stage, is activated, and a word line WL01b on the other side of the channel portion 2 in the first stage is activated.

As illustrated in FIG. 19B, for example, the pitch of word lines WL, which are led out from the memory cell array 400 to the row decoder 450, is greater than the pitch of word lines WL within the memory cell array 400. The reason for this is that the size of transistors for switching word lines within the row decoder 450 is greater than the size of memory cells MC (cell transistors CT). Accordingly, the word lines WL are spread in a widening manner, for example, from the central part in the Y direction of the memory cell array 400 toward both sides.

The other block configuration of the MRAM 40 is, for example, the same as the block configuration of FIG. 1. In addition, the points of the MRAM 40 other than the above are the same as in the above-described embodiment.

In the present embodiment, the directions of word lines WL, which are activated when the cell transistors CT are turned on, are opposite. Specifically, the pair of word lines WL, to which the common signal is delivered from the row decoder 450, is in opposite directions between the area A and the area B. Thereby, the signal lines of the row decoder 450 can be configured to be line-symmetric with respect to the dummy channel portion 5d. Thereby, the layout design of the MRAM 40 becomes easier. Further, noise due to an imbalance in wiring of signal lines, etc. can be reduced.

Besides, in the present embodiment, too, the same advantageous effects as in the above-described embodiment are obtained.

Incidentally, the number of areas of the memory cell array 400, which are divided by the dummy channel portion 5d, may be more than two.

### OTHER EMBODIMENTS

In the above embodiments, the description has been given of the examples in which the MRAMs 10 to 40 adopt the circuit configuration of the one-stage hierarchical bit line method (hierarchical source line method). However, the embodiments are not limited to these examples. The MRAM may have, for example, a circuit configuration of a hierarchical bit line method (hierarchical source line method) in which select switches are provided in multiple stages.

In the above embodiments, the description has been given of the examples in which both the select transistors STb, STs have the two-stage double-gate structure. However, the embodiments are not limited to these examples. Either of these select transistors may have other configuration such as SGT.

In the above embodiments, the description has been given of the examples in which the memory device is configured as MRAMs 10 to 40. However, the embodiments are not limited to these examples. The memory device may be, for example, a resistance change type memory device such as a ReRAM (Resistive Random Access Memory), a PRAM, or a PCRAM (Phase Change Random Access Memory).

In the above embodiments, the description has been given of the examples in which the memory device is configured as a resistance change type memory device. However, the embodiments are not limited to these examples. Further, as the memory element, for example, an element of a simple capacitor structure may be used, and a molecular memory, etc. may be used.

Besides, the structures of resistance change type memory devices are disclosed in, for instance, U.S. Patent Application Publication No. 2013/0250653 (U.S. patent application Ser. No. 13/601,492) titled “DRIVING METHOD OF SEMICONDUCTOR STORAGE DEVICE AND SEMICONDUCTOR STORAGE DEVICE”, and U.S. Patent Application Publication No. 2013/0229861 (U.S. patent application Ser. No. 13/780,791) titled “DRIVING METHOD OF SEMICONDUCTOR STORAGE DEVICE AND SEMICONDUCTOR STORAGE DEVICE”. The entirety of these patent applications is incorporated in the present specification by reference.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A memory device comprising:
a memory element; and
a transistor including a semiconductor layer and a plurality of gates,
wherein the plurality of gates include:
a first set of gates, the gates being disposed in a manner to sandwich the semiconductor layer, and
a second set of gates, the gates being disposed in a manner to sandwich the semiconductor layer,
the gates included in the first set is disposed in a manner to separate from the gates included in the second set in a direction along a side surface of the semiconductor layer, and
when the transistor is turned on, at least a gate on one side of the semiconductor layer in the first set is activated, and at least a gate on the other side of the semiconductor layer in the second set is activated.

2. The memory device of claim 1, wherein the transistor is a cell transistor to which the memory element is connected in series.

3. The memory device of claim 2, wherein, among the plurality of gates, at least gates on one side of the semiconductor layer are shared with another cell transistor neighboring the cell transistor.

4. The memory device of claim 3, wherein the cell transistor is included in a first group,
the memory device further comprises a cell transistor included in a second group which does not share the gates of the cell transistor in the first group,
the cell transistor included in the second group includes a semiconductor layer and a plurality of gates,
the plurality of gates includes:
a first set of gates, the gates being disposed in a manner to sandwich the semiconductor layer,
a second set of gates, the gates being disposed in a manner to sandwich the semiconductor layer, and
the gates included in the first set is disposed in a manner to separate from the gates included in the second set in a direction along a side surface of the semiconductor layer,
when the cell transistor of the second group is turned on, a gate on one side of the semiconductor layer in the second set is activated, and a gate on the other side of the semiconductor layer in the first set is activated.

5. The memory device of claim 1, wherein the memory element is connected to a local wiring line, and
the transistor is a select transistor connected to the local wiring line.

6. The memory device of claim 5, wherein in the first set and the second set, the gates on both sides of the semiconductor layer are activated when the select transistor is turned on.

7. A memory device comprising:
a memory element connected to a local wiring line;
a cell transistor including a semiconductor layer and a plurality of gates, the cell transistor being connected in series to the memory element; and
a select transistor including a semiconductor layer and a plurality of gates, the select transistor being connected to the local wiring line,
wherein the plurality of gates of the cell transistor and the select transistor include:
a first set of gates, the gates being disposed in a manner to sandwich the semiconductor layer, and
a second set of gates, the gates being disposed in a manner to sandwich the semiconductor layer,
the gates included in the first set is disposed in a manner to separate from the gates included in the second set in a direction along a side surface of the semiconductor layer, and
when the memory element is operated, a gate on one side of the semiconductor layer in a first set is activated, a gate on the other side of the semiconductor layer in a second set is activated, and gates on both sides of the semiconductor layer are activated in the first set and the second set of the gates of the select transistor.

8. The memory device of claim 7, wherein one end of the memory element is connected to a first terminal of the cell transistor in series, and the other end of the memory element is connected to a second terminal of the select transistor in series.

9. The memory device of claim 8, wherein the local wiring line is a bit line.

10. The memory device of claim 7, wherein one end of the memory element is connected to a first terminal of the cell transistor in series, and a second terminal of the cell transistor is connected to a first terminal of the select transistor in series.

11. The memory device of claim 10, wherein the local wiring line is a source line.

12. The memory device of claim 1, wherein the memory element is a resistance change element.

13. The memory device of claim 1, wherein the memory element is a magnetoresistive effect element.

14. A memory device comprising:
a first select transistor electrically connecting a bit line to a global bit line;
a second select transistor electrically connecting a source line to a global source line;
a plurality of blocks each including a plurality of memory cells which are interposed between the first and second select transistors and are connected to the bit line and the source line,
wherein information of a block in which a defect occurred, among the plurality of blocks, is stored.

15. The memory device of claim 14, wherein one of the blocks includes a plurality of memory cells connected commonly to a plurality of word lines.

16. The memory device of claim 14, wherein when a write operation, a read operation and an erase operation are executed for the memory cells, the block in which the defect occurred is in a state of electrical isolation from the global bit line and global source line.

17. The memory device of claim 14, wherein each of the first and second select transistors includes a semiconductor layer and a plurality of gates, and the plurality of gates includes:
a first set of gates, the gates being disposed in a manner to sandwich the semiconductor layer,
a second set of gates, the gates being disposed in a manner to sandwich the semiconductor layer, and
the gates being included in the first set is disposed in a manner to separate from the gates included in the second set in a direction along a side surface of the semiconductor layer.

18. The memory device of claim 14, wherein each of the memory cells includes a memory element, and a cell transistor connected in series to the memory element, and
the cell transistor includes a semiconductor layer and a plurality of gates, the plurality of gates includes:
a first set of gates, the gates being disposed in a manner to sandwich the semiconductor layer,
a second set of gates, the gates being disposed in a manner to sandwich the semiconductor layer, and
the gates being included in the first set is disposed in a manner to separate from the gates included in the second set in a direction along a side surface of the semiconductor layer.

19. The memory device of claim 18, wherein the memory element is a resistance change element.

20. The memory device of claim 18, wherein the memory element is a magnetoresistive effect element.
